(19) United States
(12) Patent Application Publication
(10) Pub. No.: US 2025/0096725 A1
(43) Pub. Date: Mar. 20, 2025

(54) WINDOW-INTEGRATED TRANSPARENT PHOTOVOLTAIC MODULE

(71) Applicant: Ubiquitous Energy, Inc., Redwood City, CA (US)

(72) Inventors: Miles Barr, Redwood City, CA (US); Ian Millard, Palo Alto, CA (US); Rachel Molaro, Belmont, CA (US); Richa Pandey, Sunnyvale, CA (US); Veeral Hardev, Redwood City, CA (US); Damon Hess, Portland, OR (US)

(73) Assignee: Ubiquitous Energy, Inc., Redwood City, CA (US)

(21) Appl. No.: 18/642,631

(22) Filed: Apr. 22, 2024

Related U.S. Application Data
(63) Continuation of application No. 15/867,394, filed on Jan. 10, 2018, now abandoned.
(60) Provisional application No. 62/444,577, filed on Jan. 10, 2017.

(51) Int. Cl. H02S 30/10; E06B 3/66; E06B 3/67; E06B 9/24; E06B 9/264; G02F 1/15; G02F 1/153; G02F 1/155; G02F 1/157; H01L 31/0224; H01L 31/048; H01L 31/054; H02S 20/22; H02S 20/26

(52) U.S. Cl. CPC H02S 30/10; E06B 3/66; E06B 3/6722; E06B 9/24; E06B 9/264; G02F 1/15; G02F 1/157; H02S 20/22; H02S 20/26; H10F 19/80; H10F 19/807; H10F 77/244; H10F 77/492; E06B 2009/2464; E06B 2009/2476; E06B 2009/2643; G02F 1/153; G02F 1/155; Y02E 10/52

(57) ABSTRACT

An electricity generating window includes a first glass pane, a second glass pane, and a photovoltaic device formed on an inner surface of the first glass pane or an inner surface of the second glass pane. The photovoltaic device includes a first transparent electrode layer, a second transparent electrode layer, and one or more active layers configured to transmit visible light and absorb ultraviolet or near-infrared light. In some embodiments, the electricity generating window also includes a spacer configured to separate the first glass pane and the second glass pane by a cavity. In some embodiments, the electricity generating window also includes one or more functional layers, such as an electrochromic layer or a low-E layer for reflecting infrared light.

### CROSS-REFERENCES TO RELATED APPLICATIONS

This application is a continuation of U.S. patent application Ser. No. 15/867,394, filed Jan. 10, 2018; which claims priority to U.S. Provisional Patent Application No. 62/444,577, filed Jan. 10, 2017, the disclosures of which are hereby incorporated by reference in their entirety for all purposes.

### FIELD OF THE INVENTION

This invention relates generally to the field of photovoltaic modules and devices, and more particularly, to window-integrated transparent photovoltaic modules.

### BACKGROUND OF THE INVENTION

Building-integrated photovoltaic (PV) technologies have been used to convert solar energy irradiated onto buildings into electrical energy that can be used or stored at the building or can be fed back to the power grid. However, such technologies have not been widely used due to, for example, the cost, non-transparency, and aesthetic issues associated with mounting traditional PV cells on locations such as windows of buildings.

### SUMMARY OF THE INVENTION

Techniques disclosed herein relate to photovoltaic modules, such as window-integrated photovoltaic modules. The window-integrated photovoltaic modules may include visibly transparent PV layers that can convert light outside of the visible band into electrical energy. For example, one or more visibly transparent PV layers may be integrated into insulated glazing units (IGUs) that may include two or more window panes (also referred to as panels or lites) separated by a gap for reducing heat transfer. The visibly transparent PV layers may convert infrared (IR) and/or ultraviolet (UV) light into electrical energy, and thus can generate electrical energy and, at the same time, further reduce building heating by the IR light while allowing visible light to pass through, for example, for illumination purposes. In some embodiments, other functional layers may also be integrated into the PV layer or the IGU to add additional functional to the IGU and/or to further improve the overall performance of the IGU.

According to some embodiments, an electricity generating window may include a first glass pane, a second glass pane, and a photovoltaic device formed on an inner surface of the first glass pane or an inner surface of the second glass pane. The photovoltaic device may include a first transparent electrode layer, a second transparent electrode layer, and one or more active layers configured to transmit visible light and absorb ultraviolet or near-infrared light to convert the ultraviolet or near-infrared light into electricity. In some embodiments, the photovoltaic device may be configured to act both as a photovoltaic device and as a low-E layer for reflecting infrared light. In some implementations, the photovoltaic device may be laminated between the first glass pane and the second glass pane. In some embodiments, the electricity generating window may also include a functional device electrically coupled to the photovoltaic device. In some embodiments, the functional device may include an electrochromic device.

In some embodiments, the electricity generating window may also include a first busbar in contact with the first transparent electrode layer, a second busbar in contact with the second transparent electrode layer, and a spacer separating the first glass pane and the second glass pane by a cavity. The spacer may form a closed loop outside a perimeter of the photovoltaic device but within a perimeter of the first glass pane or the second glass pane. The first busbar and second busbar may be within a perimeter formed by the spacer or underneath the spacer, each of the first busbar and second busbar extending along an edge of the photovoltaic device. In some embodiments, the electricity generating window may also include an encapsulation layer on the photovoltaic device and within the perimeter formed by the spacer. In some implementations, the encapsulation layer may include one or more thin film encapsulation layers. In some implementations, the encapsulation layer may include a low emissivity (low-E) layer for reflecting infrared light. In some implementations, the encapsulation layer may include a glass panel or a laminated barrier layer. In some implementations, the electricity generating window may also include two wires, each wire electrically connected to the first busbar or the second busbar and passing through the spacer via an air-tight seal in the spacer.

According to some embodiments, an electrochromic window may include a first glass pane, a photovoltaic device formed on an inner surface of the first glass pane, a barrier layer, a second glass pane, and an electrochromic layer. The photovoltaic device may include a first transparent electrode layer, a second transparent electrode layer, and one or more active layers configured to absorb ultraviolet or near-infrared light and transmit visible light. The electrochromic layer may be positioned between the barrier layer and the second glass pane, and may be electrically coupled to the first transparent electrode layer and the second transparent electrode layer.

According to some embodiments, a method for fabricating an electricity generating window may include forming a photovoltaic device on a top surface of a first glass pane, and attaching a second glass pane on top of the photovoltaic device, where the second glass pane is separate from the photovoltaic device by a distance. The photovoltaic device may include a first transparent electrode layer, one or more active layers configured to absorb ultraviolet or near-infrared light and transmit visible light, and a second transparent electrode layer.

In some embodiments, the method for fabricating the electricity generating window may also include forming a first busbar in contact with the first transparent electrode layer, forming a second busbar in contact with the second transparent electrode layer, and depositing an encapsulation layer on the photovoltaic device. In some embodiments, attaching the second glass pane on top of the photovoltaic device may include attaching a spacer on the encapsulation layer, and attaching the second glass pane on the spacer. The spacer may form a closed loop outside a perimeter of the photovoltaic device but within a perimeter of the first glass pane or the second glass pane. The first busbar and second busbar may be within a perimeter formed by the spacer or underneath the spacer, each of the first busbar and second busbar extending along an edge of the photovoltaic device. In some embodiments, depositing the encapsulation layer on the photovoltaic device may include depositing one or more thin film layers. In some embodiments, the method may further include forming a low-E layer for reflecting infrared light on a bottom surface of the second glass pane or above the photovoltaic device before attaching the second glass pane on top of the photovoltaic device. In some embodiments, the method may further include forming an electrochromic layer on the second glass pane or above the photovoltaic device, and electrically coupling the electrochromic layer to the photovoltaic device.

Numerous benefits are achieved by way of the present invention over conventional techniques. For example, embodiments of the present invention can be used for both thermal isolation and solar energy harvest, without affecting the illumination of the internal of the building by the visible light. By converting the IR light (a major heat source) entering the IGU into electrical power, the PV layers may help to improve the overall thermal performance of the IGUs, such as thermal emissivity and solar heat gain coefficient, thus reducing the heating and/or cooling costs of the building. Because the PV layers are substantially transparent to visible light, visible light from a light source (e.g., the sun) may enter the building through the IGUs with little loss for illuminate purpose. In various embodiments, the PV layers may also be integrated into the IGUs with other functional layers (e.g., an electrochromic layer) according to different configurations and may provide powers for these functional layers. Thus, the aesthetics of existing windows and/or glass curtain walls may be maintained or improved to enabling more freedom for architectural adoption. These and other embodiments of the invention along with many of its advantages and features are described in more detail in conjunction with the text below and attached figures.

### BRIEF DESCRIPTION OF THE DRAWINGS

FIG. 1A is a top view of an example insulated glazing unit (IGU);

FIG. 1B is a cross-sectional view of an example IGU;

FIG. 2A illustrates an example transparent photovoltaic (PV) module according to certain embodiments;

FIG. 2B illustrates the integration of the transparent PV module into an IGU according to certain embodiments;

FIG. 2C illustrates the integration of an IGU with a transparent PV module into windows of a buildings according to certain embodiments;

FIG. 3A shows the AM 1.5 global solar spectrum and the photopic response of the human eye;

FIG. 3B shows the single-junction power conversion efficiency of a transparent excitonic solar cell as a function of the cell energy bandgap according to certain embodiments;

FIG. 3C shows the power conversion efficiency of a solar cell as a function of the number of transparent junctions in the solar cell according to certain embodiments;

FIG. 3D shows the CIE color space chromaticity diagram;

FIGS. 4A-4D illustrate various configurations of PV layer(s) in a double-pane IGU according to certain embodiments;

FIGS. 5A-5D illustrate various configurations of PV layer(s) in a multiple-pane IGU according to certain embodiments;

FIGS. 6A-6D illustrate various configurations of IGUs having a PV layer and an encapsulation layer according to certain embodiments;

FIGS. 7A-7C illustrate various methods for encapsulating a PV layer according to certain embodiments;

FIGS. 8A-8D illustrate various methods for encapsulating a PV layer before or after assembling an IGU according to certain embodiments;

FIGS. 9A-9F illustrate an example IGU including a PV layer, an encapsulation layer, an IGU spacer, and PV contacts according to certain embodiments;

FIGS. 10A-10G illustrate an example IGU including a PV layer, an encapsulation layer, an IGU spacer, and PV contacts according to certain embodiments;

FIGS. 11A-11F illustrate an example IGU including a PV layer, an encapsulation layer, an IGU spacer, and PV contacts according to certain embodiments;

FIGS. 12A-12F illustrate an example IGU including a PV layer, an encapsulation layer, an IGU spacer, and PV contacts according to certain embodiments;

FIG. 13A illustrates an example IGU with an integrated electrochromic module according to certain embodiments;

FIG. 13B illustrates an example IGU with integrated sensor(s) according to certain embodiments;

FIG. 13C illustrates an example IGU with integrated internal blinds according to certain embodiments;

FIG. 13D illustrates an example IGU with an integrated rechargeable battery according to certain embodiments;

FIG. 14A is a top view of an example IGU with electrical wires passing through the spacer according to certain embodiments;

FIG. 14B is cross-sectional view of the example IGU with electrical wires passing through a spacer according to certain embodiments;

FIGS. 15A-15D illustrate various methods for transferring electrical energy out of an IGU through the IGU spacer according to certain embodiments;

FIGS. 16A-16B illustrate an example IGU having PV contacts outside of the IGU spacer according to certain embodiments;

FIGS. 17A-17B illustrate an example IGU having PV contacts on an exterior surface of the IGU according to certain embodiments;

FIGS. 18A-18F illustrate various configurations of PV contacts on example IGUs according to certain embodiments;

FIGS. 19A-19B illustrate example IGUs including other functional layer(s) in addition to the PV layer according to certain embodiments;

FIGS. 20A-20D illustrate various configurations of an example IGU including other functional layer(s) in addition to the PV layer according to certain embodiments;

FIGS. 21A-21B illustrate example IGUs including a functional layer and a PV layer on a same IGU glass pane according to certain embodiments;

FIGS. 22A-22C illustrate example IGUs including a functional layer and a PV layer on different IGU glass panes according to certain embodiments;

FIG. 23A illustrates an example IGU including multiple functional layers according to certain embodiments;

FIG. 23B illustrates an example IGU including multiple PV layers according to certain embodiments;

FIGS. 24A-24B illustrate example IGUs including a low-Emissivity (low-E) layer according to certain embodiments;

FIG. 25 is an exploded view of an example IGU according to certain embodiments;

FIG. 26 is an exploded view of an example IGU including an electrochromic layer according to certain embodiments;

FIG. 27 is an exploded view of an example IGU including an electrochromic layer according to certain embodiments;

FIG. 28 is an exploded view of an example IGU according to certain embodiments;

FIG. 29 illustrates the configuration of an example IGU according to certain embodiments;

FIGS. 30A-30D illustrate various components of the example IGU shown in FIG. 29 according to certain embodiments;

FIGS. 31A-31D show the fully assembled example IGU of FIG. 29 according to certain embodiments;

FIG. 32A illustrates transmission spectra of two example PV materials according to certain embodiments;

FIG. 32B illustrates front reflection spectra of two example PV materials according to certain embodiments;

FIG. 33A illustrates an example IGU;

FIG. 33B illustrates an example IGU including a low-E layer; and

FIG. 33C illustrates an example IGU including a PV layer according to certain embodiments.

### DETAILED DESCRIPTION OF THE INVENTION

Described herein are improved windows including transparent photovoltaic (PV) module(s). One or more visibly transparent PV layers may be integrated into insulated glazing units (IGUs) used in windows of buildings or other structures (e.g., a vehicle). The PV layers integrated into the IGUs can be used to generate electrical power for the building or other installation site by converting light outside of visible band (e.g., infrared (IR) or ultraviolet (UV)) into electrical power. By converting the IR light entering the IGU into electrical power, the PV layers may also help to improve the overall thermal performance of the IGUs, such as thermal emissivity and solar heat gain coefficient, thus reducing the heating and/or cooling costs of the building. Because the PV layers are substantially transparent to visible light, visible light from a light source (e.g., the sun) may enter the building through the IGUs with little loss to illuminate the interior of the building. In various embodiments, the PV layers may also be integrated into the IGUs with other functional layers according to different configurations and may provide power for these functional layers. In some embodiments, the PV layers may also be configured as multifunctional layers. Various embodiments of IGUs with integrated transparent PV layer(s) are detailed below.

As used herein, the term transparent means at least partial transmission of visible light. A material may be transparent to a light beam if the light beam can pass through the material with a relatively high transmission rate, such as greater than 20%, 30%, 50%, 60%, 75%, 80%, 90%, 95%, or higher, where other portions of the light beam may be scattered, reflected, or absorbed by the material. The transmission rate (i.e., transmissivity) may be represented by either a photopically weighted or an unweighted average transmission rate over a range of wavelengths, or the lowest transmission rate over a range of wavelengths, such as the visible wavelength range.

An insulation glazing unit generally includes two or more glass window panes (also referred to as panels or lites) separated by a vacuum or gas filled gap (also referred to as space or cavity) to reduce heat transfer across windows of a building. IGUs may also be used for acoustic insulations. Insulating glass units may be manufactured using glass with a thickness in the range of, for example, about 1 to 10 mm, or more for some special applications. One or more spacers may be used to separate the glass window panes and set the distance between the glass window panes. As used herein, an inner, interior, or internal surface of an IGU or an inner, interior, or internal surface of a glass pane of the IGU may refer to a surface of the glass pane that is facing or adjacent to the vacuum or gas filled gap or space. An outer, exterior, or external surface of an IGU or an outer, exterior, or external surface of a glass pane of the IGU may refer to a surface of the glass pane that is facing or adjacent to the external environment or the interior of a building or other structures.

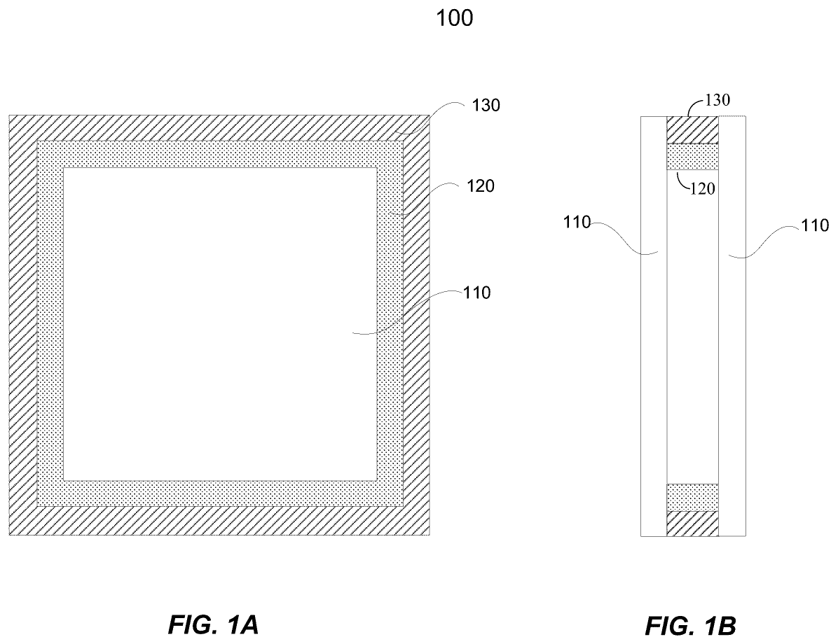

FIG. 1A is a top view of an example insulated glazing unit (IGU) 100. FIG. 1B is a cross-sectional view of example IGU 100. IGU 100 is a double glazing unit including two IGU glass panes 110, a spacer 120, and an edge sealant 130. IGU glass panes 110 may be of any suitable thickness depending on the application. Spacer 120 may separate IGU glass panes 110 and define a gap (also referred to as a space or cavity) with IGU glass panes 110. Spacer 120 may also be referred to as a spacer seal. In some embodiments, spacer 120 may include desiccant to remove moisture from the gap between IGU glass panes 110. The gap or space may be a vacuum or may be filled with gas, and may help to reduce heat transferred into or out of the building. Different kinds of gas may be used to fill the gap or space inside the IGU. Some examples of the gas may include Argon or other noble gas. As used herein, the term “air gap” and “gap” may refer to a cavity including any gas or no gas (vacuum). Edge sealant 130 may help to prevent moisture from entering the gap inside IGU 100. Spacer 120 and edge sealant 130 may collectively be referred to as a spacer seal. In some embodiments, films of various materials may also be deposited on IGU glass panes 110 for different purposes, such as UV-light blocking or IR-reflection to reduce building heating.

One or more PV layers may also be integrated into the IGUs, such as being deposited on the IGU glass panes. Previous efforts to produce photovoltaic energy-harvesting windows generally focus on either optically-thin active layers or spatially segmented inorganic PVs with light absorption in the visible spectrum. These approaches suffer from an inherent tradeoff between the power conversion efficiency (PCE) and the visible transmittance (VT) because these two parameters may be difficult to be optimized simultaneously. Architectural adoption of typical PV cells is further impeded due to the non-uniform absorption of light within the visible spectrum, which may result in poor color rendering index (CRI) (e.g., high colored tinting) and poor natural lighting quality.

According to certain embodiments, a visibly transparent PV layer may be used in IGUs for both harvesting solar energy and controlling solar thermal transmission into the building. In addition, the visibly transparent, UV/NIR-selective PV layer may avoid the aesthetic tradeoffs (low VT or CRI) that impede the architectural adoption. In some embodiments, the transparent PV layer may be configured in other ways as well, including semi-transparent, tinted, or colorful. In some embodiments, the transparent PV layer may include luminescent solar concentrators, segmented inorganic, silicon, GaAs, CIGS, CdTe, quantum dot, organic, or other materials. More details of the materials and structures for the PV layer may be found in, for example, U.S. Pat. No. 9,728,735, entitled “Transparent Photovoltaic Cells,” the entire content of which is herein incorporated by reference.

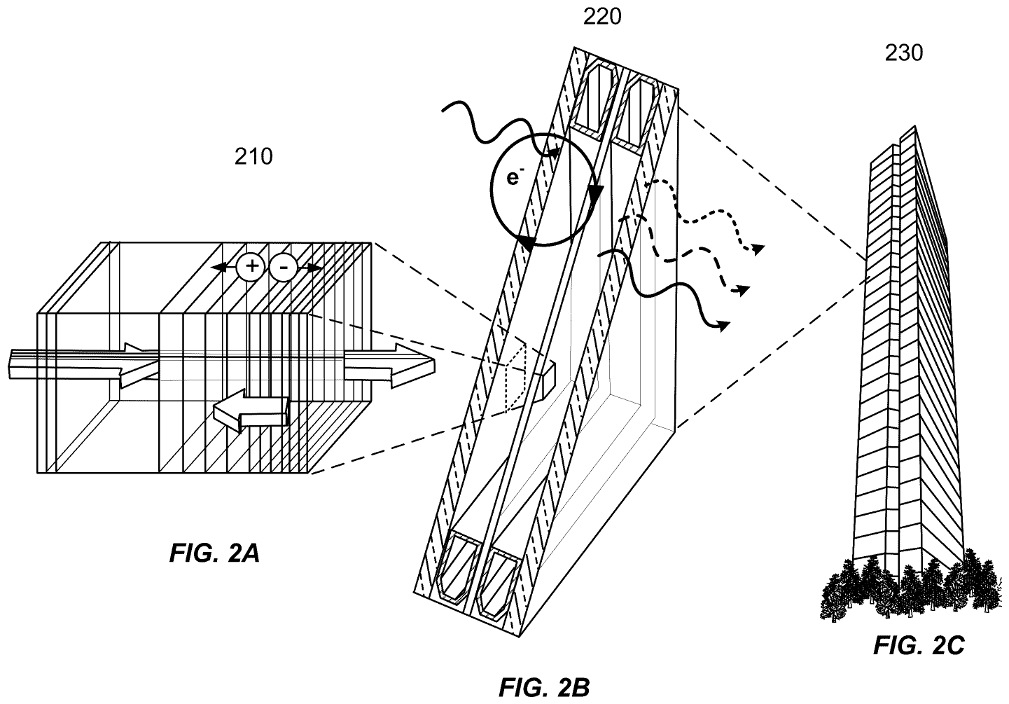

FIG. 2A illustrates an example transparent photovoltaic (PV) module 210 (also referred to as PV layer) according to certain embodiments. PV module 210 may include one or more active layers, and one or more transparent electrode layers. In some embodiments, PV module 210 may include a substrate. In some embodiments, PV module 210 may also include one or more reflecting layers. The active layers may include semiconductor materials that can absorb photons in the IR or UV light and generate electrical currents. The electrode layers may include transparent conducting electrodes (TCE) that may be fabricated by, for example, physical vapor deposition (PVD) (e.g., thermal evaporation, electron beam physical vapor deposition (EBPV), sputter deposition, or the like) of conductive oxide materials such as indium tin oxide (ITO), aluminum zinc oxide (AZO), antimony tin oxide (ATO), fluorine tin oxide (FTO), and indium zinc oxide (IZO). The transparent electrodes can also be made from different metal nanostructures such as silver nanowires and nano-cluster that can be deposited using a variety of solution-deposition techniques (e.g., spin-coating, blade-coating, or spray-coating). Transparent electrodes may also be made from graphene or carbon nanotube layers. Metals can be also be structured or patterned to form porous grid or network structures to make transparent electrodes. For example, in some embodiments, transparent electrodes may include thin metal layers such as aluminum, silver, or gold (e.g., 4 nm-12 nm) coupled with organic (e.g., small molecules) or inorganic dielectric layers (e.g., metal oxides) over a wide range of thicknesses (e.g., 1 nm-300 nm) to improve optical transmission. The reflecting layers may include reflective coatings for IR light, such as low emissivity (low-E) coating that may reduce the thermal emittance to, for example, as low as 4% or lower.

FIG. 2B illustrates the integration of transparent PV module 210 into an IGU 220 according to certain embodiments. PV module 210 may be attached to various locations on the IGU glass panes of IGU 220, such as the internal surface of the IGU glass panes that form the internal gap or space of the IGU. PV module 210 may convert IR or UV light entering IGU 220 into electrical power. In some embodiments, other functional layers, such as electrochromic material layers, may also be integrated into IGU 220.

FIG. 2C illustrates the integration of IGU 220 with transparent PV module 210 into windows of a building 230. PV module 210 integrated into IGUs installed on windows of building 230 may generate electrical power for building 230 by converting solar light outside of visible band (e.g., infrared (IR) or ultraviolet (UV)) into electrical power. By converting the IR light entering the IGUs into electrical power, PV module 210 may also help to improve the thermal performance of the IGUs, such as thermal emissivity and solar heat gain coefficient, thus reducing the heating and/or cooling costs of building 230. Because the PV modules are substantially transparent to visible light, visible light from the sun or other light sources may enter the building through the IGUs with little loss to illuminate the internal of the building. In addition, other functional layers integrated into the IGUs, such as the electrochromic layers, may be powered by the electrical power generated by PV modules 210 to, for example, change the color of the windows and the building.

In some embodiments, the transparent PV modules (or layers) may include one or more transparent PV material films (or coating layers), which may include heterojunctions of excitonic molecular semiconductors with structured absorption peaks in the near-infrared (NIR) and/or UV and allow for simultaneous optimization of the solar power conversion efficiency (PCE), visible transmittance (VT), and color rendering index (CRI). A wavelength-selective reflector can also be incorporated into the transparent PV modules to maximize infrared photocurrent within the PV film, while simultaneously rejecting transmission of unwanted infrared solar heat through the windows. Charges generated from UV and/or NIR photons can be separated at the heterojunction interface and collected by transparent electrodes, which may be interconnected through the window assembly to external electronics and/or power storage devices (e.g., a rechargeable battery). The generated electricity can then be used to power local DC networks (e.g. lighting) or inverted to AC power to supplement the building power grid. The transparent PV module may maintain or improve the aesthetics of existing windows and/or glass curtain walls, enabling more freedom for architectural adoption.

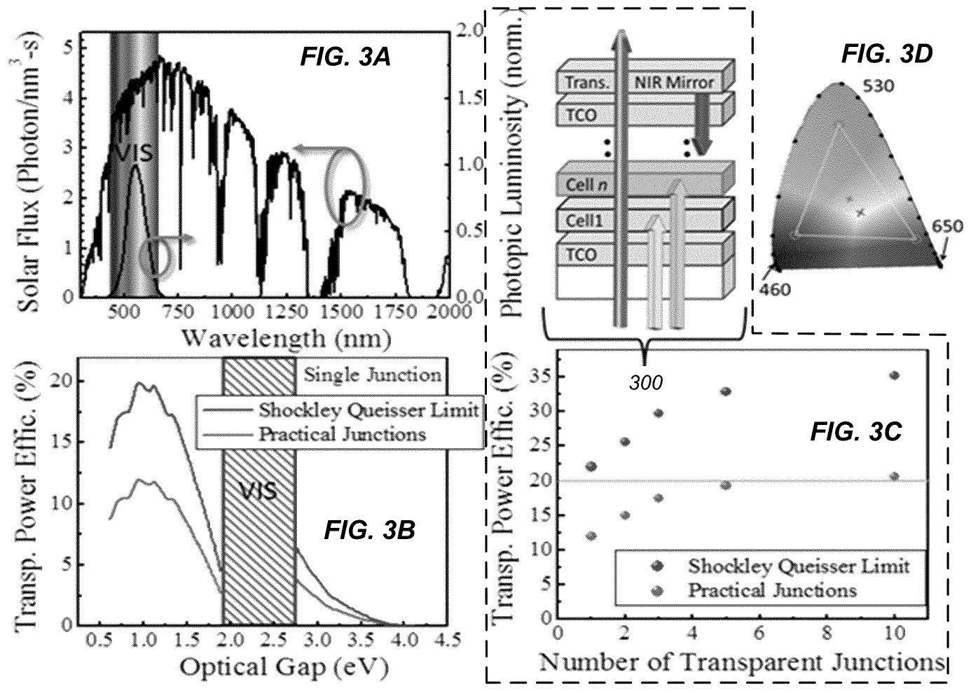

FIG. 3A shows the AM 1.5 global (AM 1.5 G) solar spectrum and the photopic response of the human eye. As shown in FIG. 3A, the human eye may be sensitive to light with a wavelength in the range of about 380 nm to about 700 nm, and may have the maximum sensitivity for green and blue light (e.g., with a peak at about 555 nm green light). On the other hand, solar light may have relative strong photon flux within a much wider wavelength range than the visible light range. For example, in the near-infrared range (e.g., above 700 nm to about 1800 or higher) and UV range, the photon flux of the solar light is also fairly high. In general, about ⅓ of the overall photon flux in the solar light is in the visible range and the remaining ⅔ of the overall photon flux are in the UV and infrared range. The NIR light may not contribute to the illumination of the interior of the building, but may heat up the interior of the building if transmitted through the window.

FIG. 3B shows the single-junction power conversion efficiency of a transparent excitonic solar cell as a function of the cell energy bandgap according to certain embodiments. As can be seen from FIG. 3B, the transparent excitonic solar cell may have a high power conversion efficiency for light with a photon energy less than about 2.0 eV (such as NIR light) or greater than about 2.8 eV (such as UV light) both theoretically and practically. Thus, the transparent excitonic solar cell can selectively convert incident ultraviolet (UV) and/or near-infrared (NIR) light into electricity, thus blocking the transmission of unwanted solar heat while selectively transmitting visible light.

FIG. 3C shows the power conversion efficiency of a solar cell 300 as a function of the number of transparent junctions in the solar cell according to certain embodiments. In some embodiments, solar cell 300 may include an optional substrate or supporting layer, two transparent electrodes, multiple junctions, and an optional visible transparent NIR reflector. The transparent electrodes and NIR reflector may be similar to the transparent electrodes and NIR reflector described above with respect to FIG. 2A. With multiple transparent junctions in a PV module, a PV power conversion efficiency of over 20% can be practically achieved.

FIG. 3D shows the CIE color space chromaticity diagram. The triangle highlights the NTSC standards. The crossbar shows the chromaticity of AM 1.5 G incident on a transparent solar cell (with a color rendering index (CRI) of 94).

Overall, solar cell 300 may achieve levelized PV energy costs (LECs) of about 0.05-0.1 $/kWhr by, for example, producing about 10-40% of DC building electricity at the point of utilization, eliminating the need for DC-AC-DC power electronics, simultaneously reducing building cooling demands by about 10-30% through the rejection of infrared solar heat, increasing the effective PV efficiency by over 5% (absolute), utilizing the materials, installation, framing, customer acquisition, and maintenance of the existing building envelope, and reducing non-module costs by over 50%.

Various embodiments of the transparent PV modules (or layers) and IGUs are described in detail below. For the purposes of explanation, specific details are set forth in order to provide a thorough understanding of certain inventive embodiments. However, it will be apparent that various embodiments may be practiced without these specific details. The figures and description are not intended to be restrictive. The word “example” is used herein to mean “serving as an example, instance, or illustration.” Any embodiment or design described herein as “example” is not necessarily to be construed as preferred or advantageous over other embodiments or designs. In some figures, the IGU is illustrated without the spacer, encapsulation, or sealing components for simplicity. Most of IGUs are shown as double glazing units in the figures, but a skilled person would readily understand that the techniques disclosed herein can be applied to glazing units with triple, quadruple, or even higher numbers of glass panes or lites.

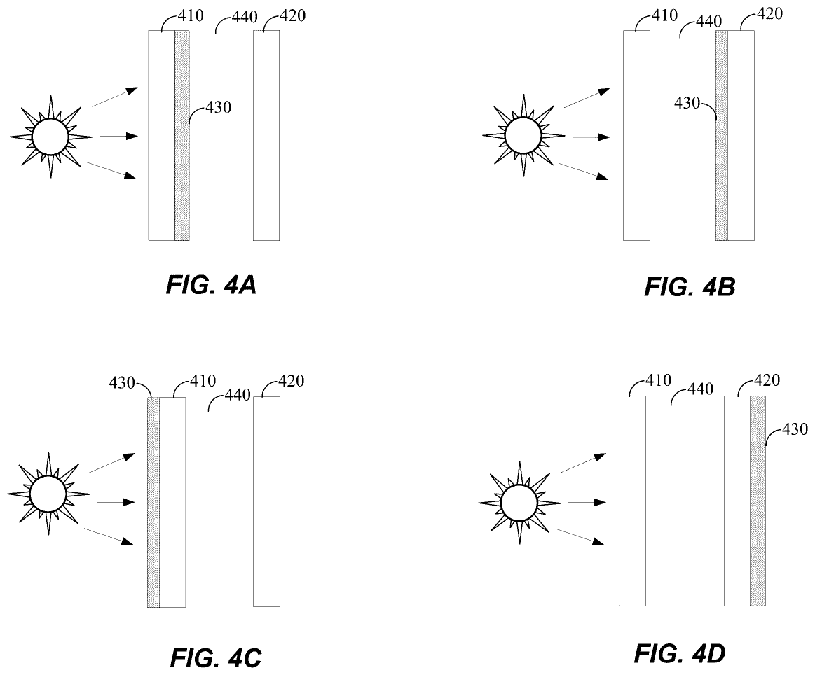

FIGS. 4A-4D illustrate various configurations of a PV layer 430 in a double-pane IGU according to certain embodiments. The double-pane IGU may include a first glass pane 410 and a second glass pane 420 that form a gap 440 in between. First glass pane 410 may be the glass pane that is closer to the external environment, and second glass pane 420 may be closer to the interior of a building after installation on the building. Solar light may first enter the IGU through first glass pane 410. PV layer 430 may include one or more active layers and two transparent electrode layers. In some implementations, PV layer 430 may also include one or more reflecting layers, such as a NIR reflecting layer. As shown in FIGS. 4A-4D, PV layer 430 can be deposited onto any surface of any IGU glass pane 410 or 420 and can be incorporated into the IGU stack on the external surface of the IGU or the internal surface of the IGU (e.g., the surfaces forming gap 440). For example, in FIG. 4A, PV layer 430 may be deposited on a surface of first glass pane 410 facing gap 440. In FIG. 4B, PV layer 430 may be deposited on a surface of second glass pane 420 facing gap 440. In FIG. 4C, PV layer 430 may be deposited on a surface of first glass pane 410 facing the external environment. In FIG. 4D, PV layer 430 may be deposited on a surface of second glass pane 420 facing the interior of the building.

In some embodiments, the PV layer can also be placed at any location within an IGU having more than two panes of glass (e.g., triple glazing units). For example, the PV layer can be placed at any location on the front or back glass panes as well as on either side of any of internal glass piece for a triple glazing unit. The PV layer may also be placed on either side of any of the glass panes of a multi-glazing units with n glass panes.

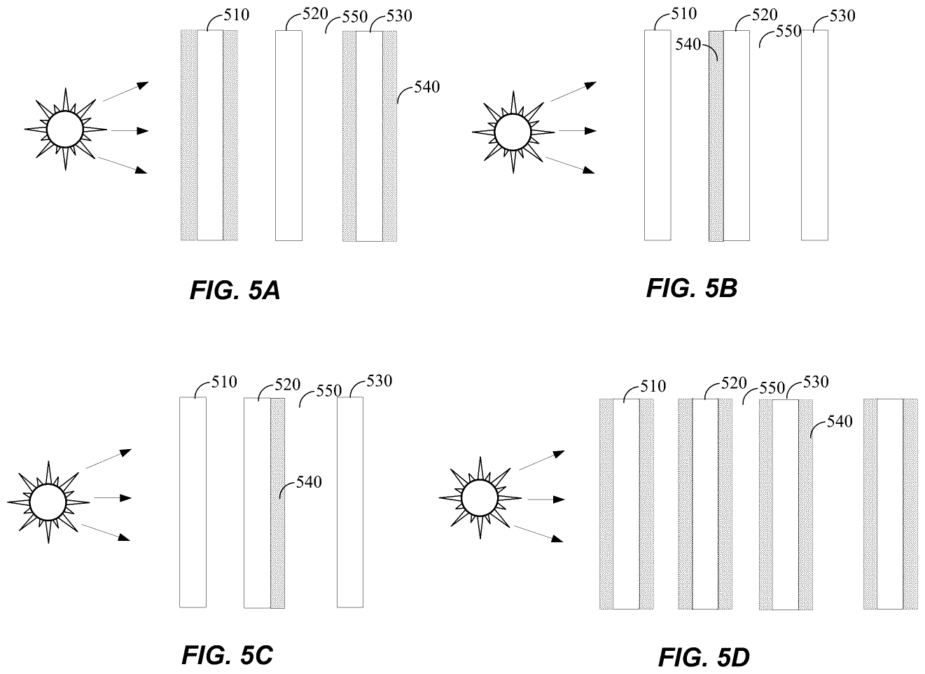

FIGS. 5A-5D illustrate various configurations of PV layer(s) 540 in a multi-pane IGU according to certain embodiments. The multi-pane IGU may include glass panes 510, 520, and 530 that may form a plurality of gaps 550. Glass pane 520 may be an internal glass pane. In FIG. 5A, PV layer(s) 540 may be placed on any surface of glass pane 510, or any surface of glass pane 530. In FIG. 5B, PV layer 540 may be placed on a surface of internal glass pane 520 that is closer to the external environment. In FIG. 5C, PV layer 540 may be placed on a surface of internal glass pane 520 that is closer to the interior of the building. FIG. 5D shows that one or more PV layers 540 may be placed on any surface of any glass pane of the multi-pane IGU.

In some embodiments where the PV layer is placed on the inner surface of the glass pane that forms the internal gap as shown in FIGS. 4A and 4B, the PV layer may be protected from moisture and oxygen by the sealing material and desiccant that protect the rest of the IGU. In other embodiments, the PV layer may be protected from, for example, moisture and oxygen by an additional encapsulation layer, such as a glass layer, a laminated barrier film, a deposited thin film, etc. For example, another piece of glass may be attached to the surface of the PV layer opposite to the glass pane of the IGU to function as a barrier. A barrier film may be adhered or laminated onto the surface of the PV layer opposite to the glass pane of the IGU and act as a barrier to moisture and oxidation chemicals (e.g., oxygen). Some forms of thin film, which may include one or more layers deposited via sputtering, atomic layer deposition, spin coating, thermal evaporation, chemical vapor deposition, or other vapor and liquid processing methods, may also be used as a barrier to protect the PV layers from moisture and oxygen. Such layers may include oxides or nitrides, such as silicon dioxide, aluminum oxide, silicon nitride, and the like.

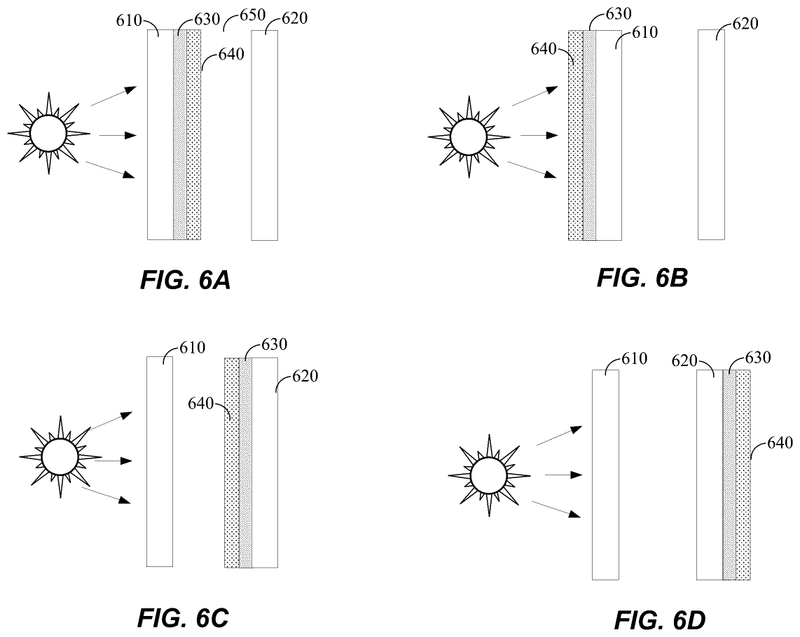

FIGS. 6A-6D illustrate various configurations of IGUs having a PV layer 630 and an encapsulation layer 640 according to certain embodiments. As described above, encapsulation layer 640 may include, for example, a glass layer, a laminated barrier film, or a deposited thin film. Encapsulation layer 640 can provide physical and chemical barrier protections on the outer surfaces of the IGU or serve as an additional barrier inside the air gap in the assembled IGU. The IGU may include a first glass pane 610 and a second glass pane 620 that, together with a spacer (not shown in FIGS. 6A-6D), form a gap 650. In the embodiment shown in FIG. 6A, PV layer 630 is placed on the inner surface of first glass pane 610 and is protected by encapsulation layer 640 from any moisture and oxidation chemicals that may be in gap 650. In the embodiment shown in FIG. 6B, PV layer 630 may be placed on the outer surface of first glass pane 610 and may be protected by encapsulation layer 640 from any moisture and oxidation chemicals that may be in the external environment. In the embodiment shown in FIG. 6C, PV layer 630 may be placed on the inner surface of second glass pane 620 and may be protected by encapsulation layer 640 from any moisture and oxidation chemicals that may be in gap 650. In the embodiment shown in FIG. 6D, PV layer 630 may be placed on the outer surface of second glass pane 620 and may be protected by encapsulation layer 640 from any moisture and oxidation chemicals that may be in the interior of the building.

Encapsulation layer 640 may be attached to PV layer 630 in many different ways. For example, for encapsulation layer 640 that includes a glass layer, PV layer 630 can be deposited on either the glass pane of the IGU or the glass layer of encapsulation layer 640, and then attached to the glass layer of encapsulation layer 640 or the glass pane, respectively. In some embodiments, PV layer 630 may either be deposited on the glass pane of the IGU and then laminated with a barrier film, or may be deposited directly onto the barrier film and then laminated on the glass pane of the IGU with the barrier film. In some embodiments, PV layer 630 may be deposited on the glass pane of the IGU and then a single-layer or multi-layer thin film may be deposited on top of PV layer 630.

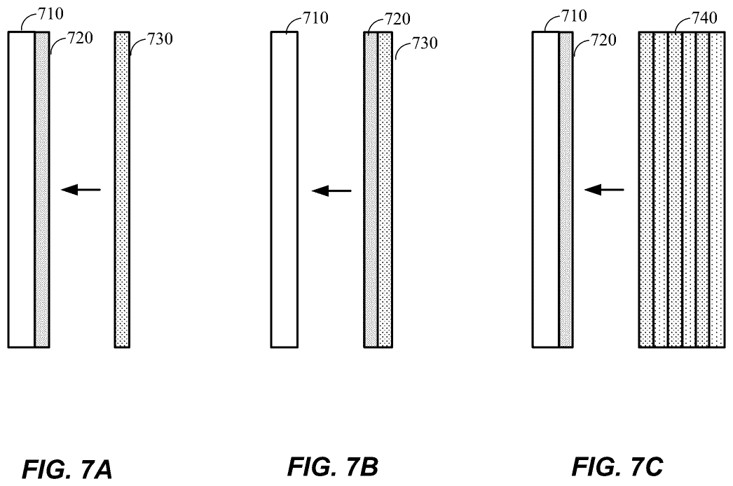

FIGS. 7A-7C illustrate various methods for encapsulating a PV layer 720 according to certain embodiments. In the embodiment shown in FIG. 7A, PV layer 720 may first be formed on a glass pane 710, and then an encapsulation layer 730, such as a glass layer, a barrier layer, or a thin film, may be formed on PV layer 720 by, for example, a direct attachment, lamination, or deposition process. In the embodiment shown in FIG. 7B, PV layer 720 may first be formed on encapsulation layer 730 (e.g., a glass layer or a barrier layer), and then PV layer 720 and encapsulation layer 730 may be attached to or laminated on glass pane 710. In the embodiment shown in FIG. 7C, PV layer 720 may first be formed on glass pane 710, and then one or more thin film layers 740 may be deposited or coated on PV layer 720 using, for example, physical vapor deposition (PVD) techniques such as thermal evaporation, electron beam physical vapor deposition (EBPV), sputter deposition, and the like, or solution-deposition techniques, such as spin-coating, blade-coating, spray-coating, and the like.

The encapsulation layer may be integrated into the IGU before or after the assembly of the IGU. For example, the PV layer may be encapsulated by one glass pane of the IGU and the encapsulation layer before the full IGU is assembled. In such embodiments, the encapsulation layer may protect the PV layer during the IGU assembly as well as after the IGU assembly. If the PV layer is on the outer surface of either glass pane of the IGU, the encapsulation may be performed after the IGU assembly.

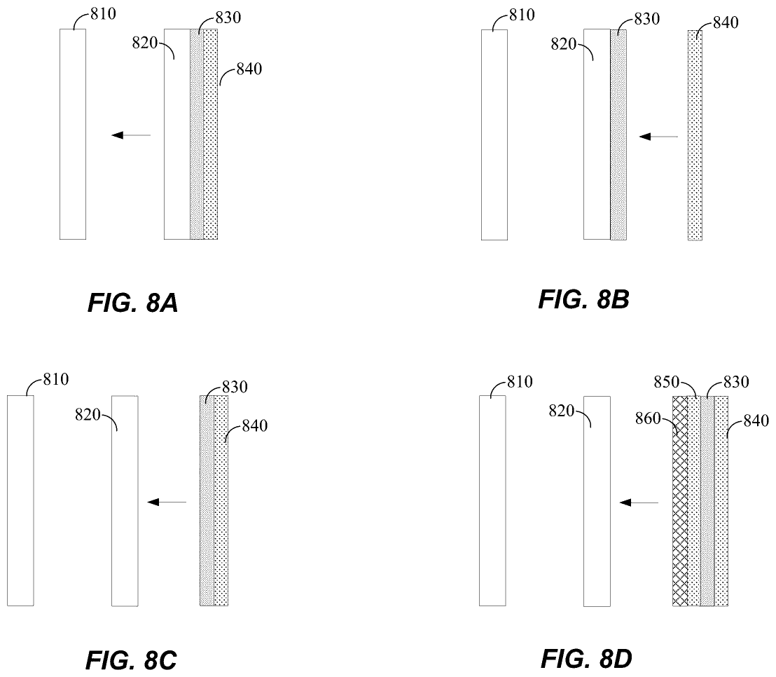

FIGS. 8A-8D illustrate various methods for encapsulating a PV layer 830 before or after assembling an IGU according to certain embodiments. As described above, the IGU may include a first glass pane 810 and a second glass pane 820. In the embodiment shown in FIG. 8A, PV layer 830 may be encapsulated by second glass pane 820 of the IGU and an encapsulation layer 840 as described above with respect to FIGS. 7A-7C. The combined second glass pane 820, PV layer 830, and encapsulation layer 840 may then be assembled with first glass pane 810 to form the fully assembled IGU.

In the embodiment shown in FIG. 8B, first glass pane 810 and second glass pane 820 may be assembled to form a dual-pane IGU first. PV layer 830 may then be formed on the outer surface of second glass pane 820 of the assembled dual-pane IGU. Finally, encapsulation layer 840 may be attached to PV layer 830 by, for example, direct attachment, lamination, deposition, or coating, as described above with respect to FIG. 7A.

In the embodiment shown in FIG. 8C, first glass pane 810 and second glass pane 820 may be assembled to form a dual-pane IGU. PV layer 830 may be formed on encapsulation layer 840 (e.g., a glass layer or a lamination barrier layer). Then PV layer 830 encapsulated with encapsulation layer 840 may be attached to the outer surface of second glass pane 820 of the dual-pane IGU by, for example, direct attachment or lamination as described above with respect to FIG. 7B.

In the embodiment shown in FIG. 8D, first glass pane 810 and second glass pane 820 may be assembled to form a dual-pane IGU. PV layer 830 may be encapsulated by encapsulation layer 840 and barrier layer 850 (or two glass layers), and the encapsulated PV layer 830 may be laminated or coated with an adhesive layer 860 to form a PV film. The PV film may be attached to the outer surface of second glass pane 820 through adhesive layer 860. The PV film may include any combination of interlayers, such as encapsulation layer 840 and/or barrier layer 850. In some embodiments, any of the barrier layers or encapsulation layer may be altered or removed. In some embodiments, barrier layer 850 may include a thin glass or plastic layer, or may be removed. In some embodiments, encapsulation layer 840 may include a thin glass or plastic layer, or may be removed. Adhesive layer 860 can be any type of optically clear adhesive that can adhere to the glass panel of the IGU for attaching the PV film to the IGU. In some embodiments, the PV film may be provided in a sheet or roll form similar to other adhesives or tapes, and may be rolled out and cut to match the desired footprint or surface area of the IGU.

Thus, techniques described above with respect to FIGS. 8B-8D may be used to add the PV layer and/or the encapsulation layer to existing IGUs that may not include any PV layer. For example, the PV layer and the encapsulation layer (and adhesive layer) assembly shown in FIGS. 8C and 8D may be laminated or otherwise attached to an outer surface of an existing IGU, and may be easily installed, removed, or replaced as needed.

As described above, a spacer may be used in an IGU to separate the glass panes and form the internal air gap. Some of the encapsulation and/or assembling techniques may be adjusted or altered to accommodate the spacer, depending on the layer stack up of the IGU.

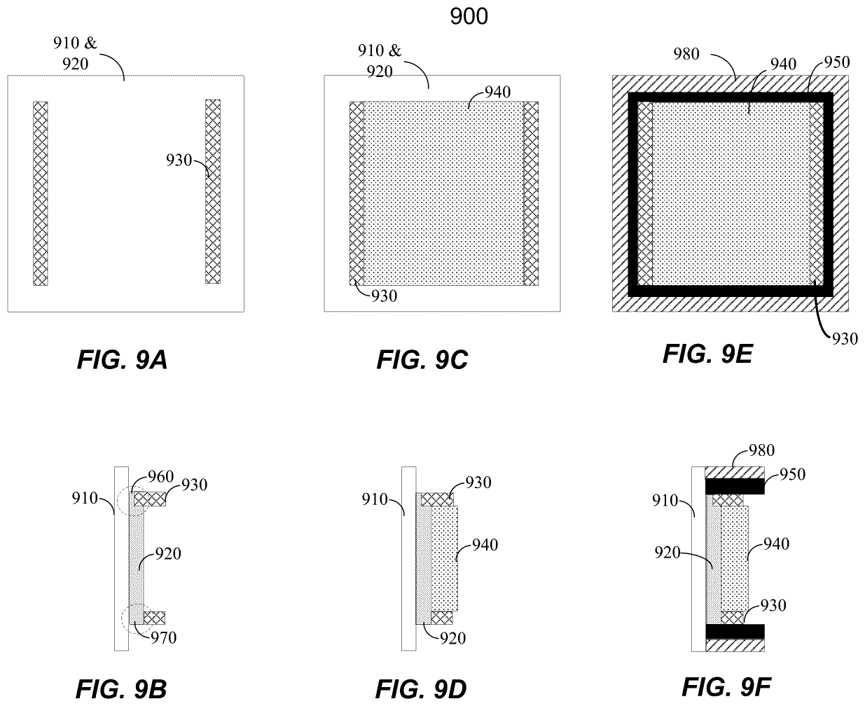

FIGS. 9A-9F illustrate an example IGU 900 including a PV layer 920 on a glass pane 910, an encapsulation layer 940, an IGU spacer 950, and PV contacts 930 according to certain embodiments. As described above with respect to FIGS. 2A and 3C, PV layer 920 may include one or more active layers and one or more transparent electrode layers (not shown in FIGS. 9A-9F). In some embodiments, PV layer 920 may also include one or more reflecting layers (not shown in FIGS. 9A-9F). In some embodiments, PV contacts 930 may include busbars in the form of a thin metal layer, such as a silver layer formed by silver ink or silver paste.

FIG. 9A is a top view of IGU 900 without encapsulation layer 940 and IGU spacer 950. FIG. 9B is a cross-sectional view of IGU 900 without encapsulation layer 940 and IGU spacer 950. As shown in FIG. 9B, in some implementations, PV layer 920 may not cover the full area of glass pane 910. Rather, PV layer 920 may align with the outer edges of PV contacts 930 and may not extend beyond the outer edges of PV contacts 930. In some implementations, some (e.g., an electrode layer) but not all layers of PV layer 920 may be under PV contacts 930 for making the electrical connection, as shown in area 960. For example, one PV contact 930 may be in contact with a first electrode layer of PV layer 920 in area 960 and another PV contact 930 may be in contact with a second electrode layer of PV layer 920 in area 970. FIG. 9C is a top view of IGU 900 with encapsulation layer 940 formed inside PV contacts 930. FIG. 9D is a cross-sectional view of IGU 900 with encapsulation layer 940 formed inside PV contacts 930. FIG. 9E is a top view of IGU 900 with encapsulation layer 940 and PV contacts 930 inside IGU spacer 950. FIG. 9F is a cross-sectional view of IGU 900 with encapsulation layer 940 and PV contacts 930 inside IGU spacer 950. FIGS. 9E and 9F also show an edge sealant 980 as described above with respect to FIGS. 1A and 1B. Since PV contacts 930 are inside of IGU spacer 950, wires may need to pass through IGU spacer 950 to make external connections for some applications. IGU 900 may have some advantages over some other IGUs with different configurations. For example, charges may not need to pass under spacer through a longer electrode or busbar path, and thus the resistive loss may be reduced as a greater distance can lead to a higher resistive loss. The outer profile of IGU 900 may be similar to standard IGUs where all additional layers and components (e.g., encapsulation glass, wiring, etc.) are internal to the IGUs. In addition, in some embodiments, the IGU spacer may be used for making the PV contacts.

In some implementations of IGU 900, PV layer 920 may cover the full area of glass pane 910. For example, in certain implementations, PV layer 920 may align with the outer edges of glass pane 910. In certain implementations, some but not all layers of PV layer 920 may extend beyond the outer edges of PV contacts 930 and/or IGU spacer 950.

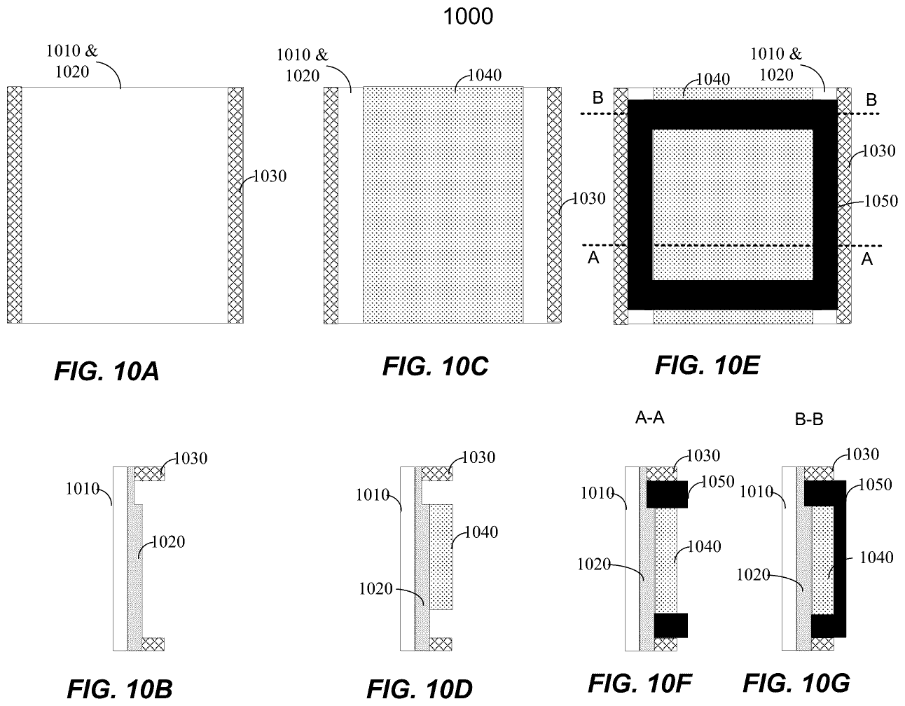

FIGS. 10A-10G illustrate an example IGU 1000 including a PV layer 1020 on a glass pane 1010, an encapsulation layer 1040, an IGU spacer 1050, and PV contacts 1030 according to certain embodiments. PV layer 1020 may include one or more active layers and one or more transparent electrode layers (not shown in FIGS. 10A-10G). PV contacts 1030 may be formed on the edges of PV layer 1020. In some embodiments, PV contacts 1030 may include, for example, busbars in the form of a thin metal layer, such as a silver layer formed by silver ink or silver paste.

FIG. 10A is a top view of IGU 1000 without encapsulation layer 1040 and IGU spacer 1050. FIG. 10B is a cross-sectional view of IGU 1000 without encapsulation layer 1040 and IGU spacer 1050. FIG. 10C is a top view of IGU 1000 with encapsulation layer 1040 formed inside PV contacts 1030. FIG. 10D is a cross-sectional view of IGU 1000 with encapsulation layer 1040 formed inside PV contacts 1030. Encapsulation layer 1040 may be separate from PV contacts 1030 by a distance. FIG. 10E is a top view of IGU 1000 with IGU spacer 1050 between encapsulation layer 1040 and PV contacts 1030. FIG. 10F is a cross-sectional view of IGU 1000 with IGU spacer 1050 between encapsulation layer 1040 and PV contacts 1030 along line A-A. FIG. 10G is a cross-sectional view of IGU 1000 with IGU spacer 1050 between encapsulation layer 1040 and PV contacts 1030 along line B-B. In IGU 1000, PV contacts 1030 are outside of IGU spacer 1050, and thus electrical wiring does not need to pass through IGU spacer 1050. In some implementations, some (e.g., an electrode layer) but not all layers of PV layer 1020 may extend to the edges of glass pane 1010 or alight with PV contacts 1030 for making electrical contacts with PV contacts 1030. As shown in FIG. 10E, encapsulation layer 1040 is partially inside IGU spacer 1050 and partially outside of IGU spacer 1050. IGU 1000 may have some advantages over some other IGUs with different configurations. For example, electrical wiring does not need to pass through IGU spacer 1050. Two edges of encapsulation layer 1040 (e.g., a glass layer) may align with the edges of glass pane 1010, allowing for easier assembly. It is also possible to use IGU spacer 1050 for PV contacts.

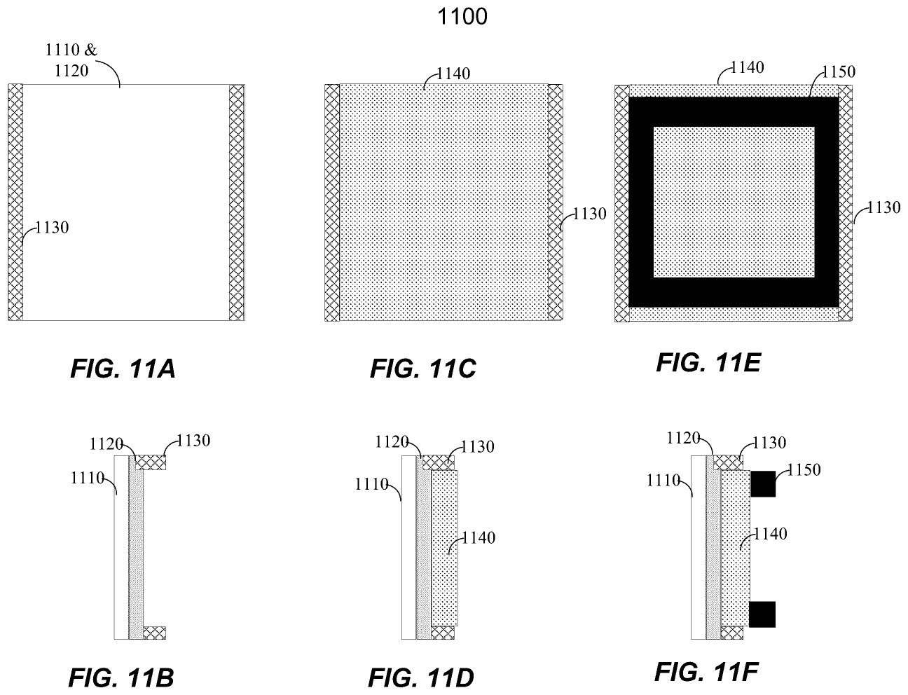

FIGS. 11A-11F illustrate an example IGU 1100 including a PV layer 1120 on a glass pane 1110, an encapsulation layer 1140, an IGU spacer 1150, and PV contacts 1130 according to certain embodiments. PV contacts 1130 may be formed on the edges of PV layer 1120 as in IGU 1000. FIG. 11A is a top view of IGU 1100 without encapsulation layer 1140 and IGU spacer 1150. FIG. 11B is a cross-sectional view of IGU 1100 without encapsulation layer 1140 and IGU spacer 1150. FIG. 11C is a top view of IGU 1100 with encapsulation layer 1140 formed inside PV contacts 1130. FIG. 11D is a cross-sectional view of IGU 1100 with encapsulation layer 1140 formed inside PV contacts 1130. Encapsulation layer 1140 may be in contact with PV contacts 1130. FIG. 11E is a top view of IGU 1100 with IGU spacer 1150 on top of encapsulation layer 1140. FIG. 11F is a cross-sectional view of IGU 1100 with IGU spacer 1150 on top of encapsulation layer 1140. In IGU 1100, PV contacts 1130 may be outside of IGU spacer 1150, and thus electrical wiring does not need to pass through IGU spacer 1150. In some implementations, some (e.g., an electrode layer) but not all layers of PV layer 1120 may extend to the edges of glass pane 1110 or alight with PV contacts 1130 for making electrical contacts with PV contacts 1130. Encapsulation layer 1140 may be partially inside IGU spacer 1150 and partially outside of IGU spacer 1150. IGU 1100 may have some advantages over some other IGUs with different configurations. For example, electrical wiring does not need to pass through IGU spacer 1150. Two edges of encapsulation layer 1140 (e.g., a glass layer) may align with the edges of glass pane 1110, allowing for easier assembly. In addition, IGU spacer 1150 does not need to have different heights at different locations as in IGU 1000 because IGU spacer 1150 can be placed entirely on encapsulation layer 1140.

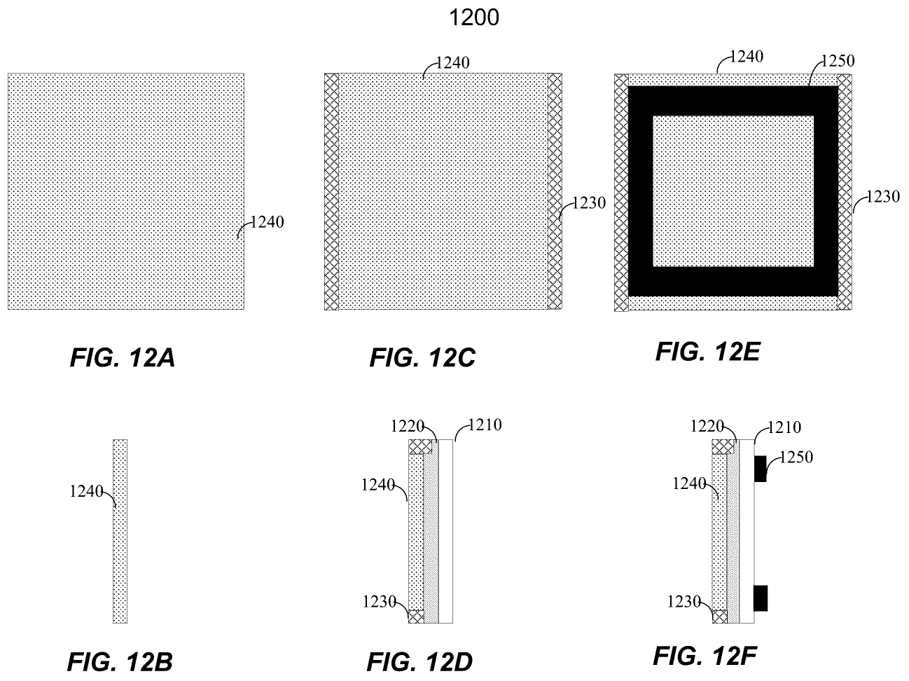

FIGS. 12A-12F illustrate an example IGU 1200 including a PV layer 1220 on a glass pane 1210, an encapsulation layer 1240, an IGU spacer 1250, and PV contacts 1230 according to certain embodiments. In IGU 1200, PV layer 1220 may be formed on the outer surface of glass pane 1210, and encapsulation layer 1240 may be formed on PV layer 1220 to protect PV layer 1220 from moisture and/or oxygen in the air inside or outside a building. PV contacts 1230 may be formed on the edge of PV layer 1220 as in IGUs 1000 and 1100. FIG. 12A is a top view of encapsulation layer 1240. FIG. 12B is a cross-sectional view of encapsulation layer 1240. FIG. 12C is a top view of IGU 1200 with PV layer 1220, encapsulation layer 1240, and PV contacts 1230 formed on the outer surface of glass pane 1210, where encapsulation layer 1240 may be inside PV contacts 1230. FIG. 12D is a cross-sectional view of IGU 1200 with PV layer 1220, encapsulation layer 1240, and PV contacts 1230 formed on the outer surface of glass pane 1210, where encapsulation layer 1240 may be inside PV contacts 1230. Encapsulation layer 1240 may be in contact with PV contacts 1230. FIG. 12E is a top view of IGU 1200 with IGU spacer 1250 on the inner surface of glass pane 1210. FIG. 12F is a cross-sectional view of IGU 1200 with IGU spacer 1250 on the inner surface of glass pane 1210. Thus, encapsulation layer 1240 and IGU spacer 1250 are on opposite side of glass pane 1210. In some implementations, some (e.g., an electrode layer) but not all layers of PV layer 1220 may extend to the edges of glass pane 1210 or alight with PV contacts 1230 for making electrical contacts with PV contacts 1230. IGU 1200 may have some advantages over some other IGUs with different configurations. For example, electrical wiring does not need to pass through IGU spacer 1250 because PV contacts 1230 are on the opposite side of glass pane 1210. Two edges of encapsulation layer 1240 (e.g., a glass layer) may align with two edges of glass pane 1210, allowing for easier assembly. In addition, IGU spacer 1250 do not need to have different heights at different locations as in IGU 1000 because IGU spacer 1250 may be placed entirely on glass pane 1210.

In some embodiments, some wiring or other electrical connections may be used in order to transport the power generated by the PV layer to a location where the power may be used or stored by an electrical device. In some applications, the electrical power generated from solar power may be used directly inside the IGU spacer. For example, in some applications, there may be a functional device internal to some IGUs (e.g., in the gap between glass panes), the PV layer can be directly wired or otherwise electrically connected to the functional device and any supporting electronics internal to the IGU. These functional devices may include an electrochromic layer/device for window tinting, various kinds of sensors, power controls for internal blinds, or other devices that may require electrical power. In some implementations, the PV layer may be connected to a rechargeable battery, which may in turn power the internal device at a later time when needed.

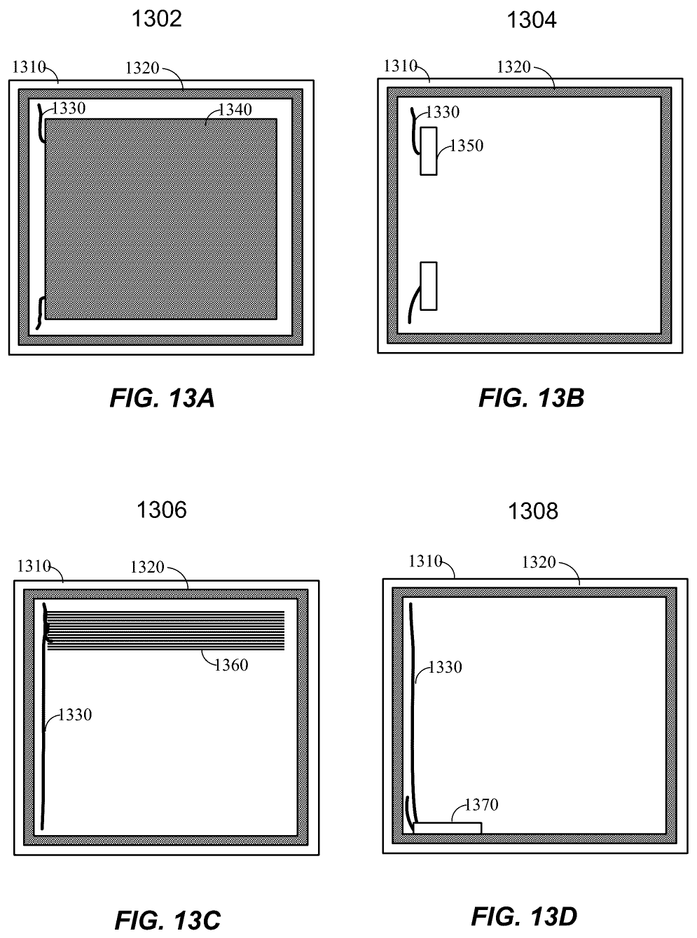

FIG. 13A illustrates an example IGU 1302 with an integrated electrochromic module 1340 according to certain embodiments. IGU 1302 may include an assembly 1310 including a glass pane and a PV layer. Electrochromic module 1340 may be in the form an electrochromic layer and may be placed in an internal cavity formed by assembly 1310 and a spacer 1320. The PV layer of assembly 1310 may be connected to electrochromic module 1340 through electrical wires 1330 to power electrochromic module 1340. In some implementations, wires 1330 may be embedded in or covered by spacer 1320, or otherwise be hidden by spacer 1320.

FIG. 13B illustrates an example IGU 1304 with integrated sensor(s) 1350 according to certain embodiments. IGU 1304 may include assembly 1310 and spacer 1320. Integrated sensor(s) 1350 may be placed in the internal cavity formed by assembly 1310 and spacer 1320. The PV layer of assembly 1310 may be connected to integrated sensor(s) 1350 through electrical wires 1330 to power integrated sensor(s) 1350. In some implementations, wires 1330 may be embedded in or covered by spacer 1320, or otherwise be hidden by spacer 1320.

FIG. 13C illustrates an example IGU 1306 with integrated internal blinds 1360 according to certain embodiments. IGU 1306 may include assembly 1310 and spacer 1320. Internal blinds 1360 may be placed in the internal cavity formed by assembly 1310 and spacer 1320. The PV layer of assembly 1310 may be connected to the controller of internal blinds 1360 through electrical wires 1330 to power the controller of internal blinds 1360. In some implementations, wires 1330 may be embedded in or covered by spacer 1320, or otherwise be hidden by spacer 1320.

FIG. 13D illustrates an example IGU 1308 with an integrated rechargeable battery 1370 according to certain embodiments. IGU 1308 may include assembly 1310 and spacer 1320. Rechargeable battery 1370 may be placed in an internal cavity formed by assembly 1310 and spacer 1320. The PV layer of assembly 1310 may be connected to rechargeable battery 1370 through electrical wires 1330 to charge rechargeable battery 1370. Rechargeable battery 1370 may be used to power other internal or external devices when needed. In some implementations, wires 1330 may be embedded in or covered by spacer 1320, or otherwise be hidden by spacer 1320.

In some applications, the electrical power generated from solar power may need to be transported outside of the internal gap of the IGU if the power consuming device is not in the internal gap or if the PV contacts are not located outside of the internal gap and the spacer. Some techniques for transporting the electrical power generated by the PV layer out of the IGU through the spacer are described in detail below.

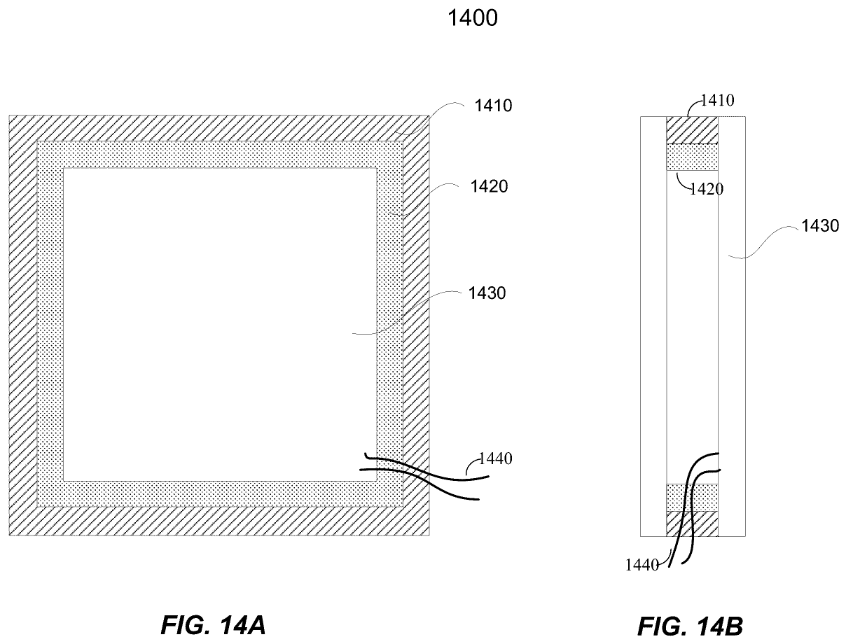

FIG. 14A is a top view of an example IGU 1400 with electrical wires 1440 passing through a spacer 1420 and a sealant 1410 according to certain embodiments. FIG. 14B is a cross-sectional view of IGU 1400. IGU 1400 may include an assembly 1430 including a glass pane and a PV layer. Electrical wires 1440 may be connected to the PV layer, and pass through spacer 1420 and sealant 1410 to the outside of IGU 1400.

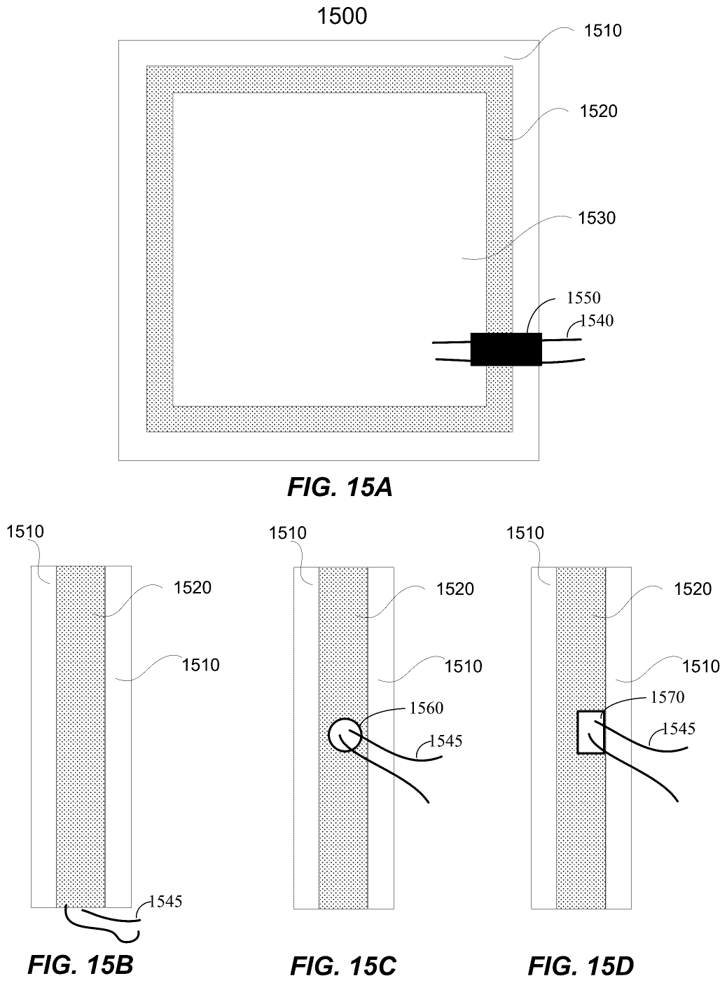

FIGS. 15A-15D illustrate various methods for transferring electrical energy out of an IGU 1500 through an IGU spacer 1520 according to certain embodiments. IGU 1500 may include a glass pane 1510, IGU spacer 1520, and a PV layer 1530 formed in glass pane 1510. FIG. 15A shows that a pre-installed/sealed connector 1550 in IGU spacer 1520 may be used to pass power from the PV layer inside of IGU spacer 1520 to external cords or other electrical connections 1540. FIG. 15B shows that electrical wires 1545 may pass through a corner gap formed in IGU spacer 1520. FIG. 15C shows that electrical wires 1545 may pass a hole 1560 in the middle of IGU spacer 1520. FIG. 15D shows that electrical wires 1545 may pass a hole 1570 at the edge of IGU spacer 1520.

In some embodiments, the PV layer may be inside the IGU, and the PV contacts on the PV layer may be outside of the spacer but may be covered by the sealant. The power generated by the PV layer may be transported from the inside of the IGU but may not need to pass through the spacer.

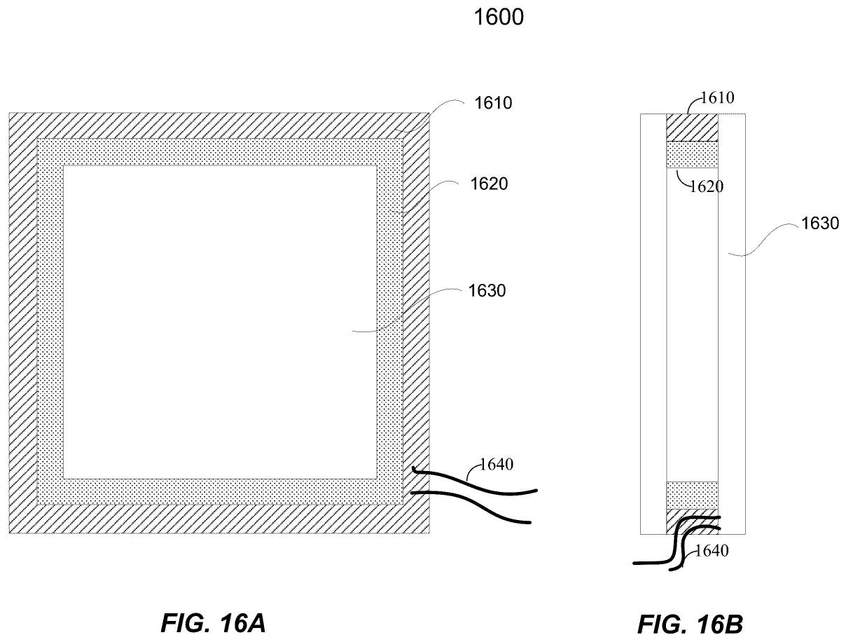

FIGS. 16A-16B illustrate an example IGU 1600 having PV contacts outside of an IGU spacer 1620 according to certain embodiments. FIG. 16A is a top view of IGU 1600 and FIG. 16B is a cross-sectional view of IGU 1600. IGU 1600 may include an assembly 1630 including a glass pane and a PV layer. Electrical wires 1640 may be connected to the PV layer in an area outside of spacer 1620, and pass through sealant 1610 to the outside of IGU 1600.

In some embodiments, the PV layer may be placed on an exterior surface of the IGU. In such cases, the electrical wires may not need to pass through the spacer, and may be connected to the PV layer at any location inside or outside of the regions covering the spacer.

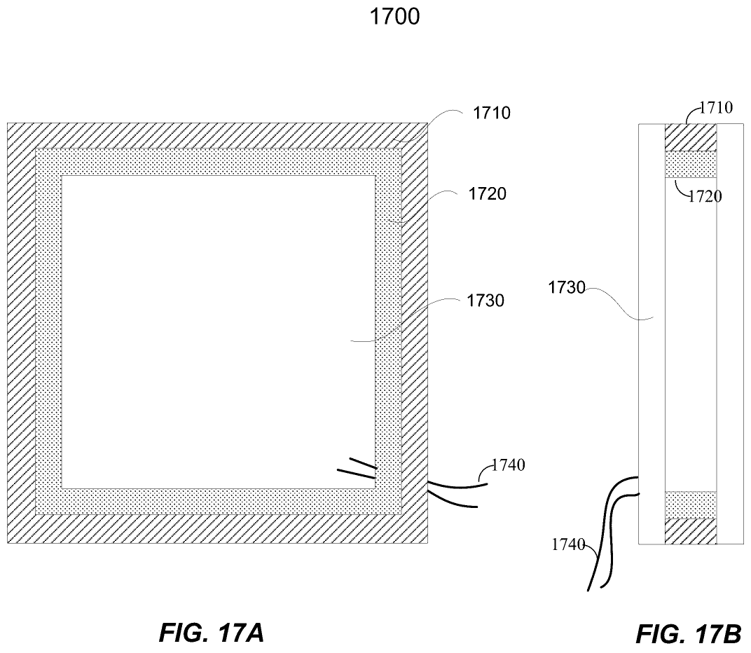

FIGS. 17A-17B illustrate an example IGU 1700 having PV contacts on an exterior surface of IGU 1700 according to certain embodiments. FIG. 17A is a top view of IGU 1700 and FIG. 17B is a cross-sectional view of IGU 1700. IGU 1700 may include an assembly 1730 including a glass pane and a PV layer on the outer surface of the glass pane, a spacer 1720, and a sealant 1710. Electrical wires 1740 may be connected to the PV layer at any location inside, outside, or at the region covering spacer 1720.

The contacts with the PV layer may allow electrical power to be transported to wiring or other electronic components for the desired applications. Many different techniques may be used for making contact with the PV layer whether the PV layer is on an inner or outer surface of the IGU. Examples of these techniques may include contacts embedded in or connected directly to the spacer component (e.g., an adhesive), contacts through soldered connections, contacts through conductive press fittings, contacts using conductive tapes, or contacts through a flex connector. In some embodiments, busbars rather than wiring may be used to transport charges from one location on a surface of the PV layer to another location on the same surface where a functional device may be located at or attached to.

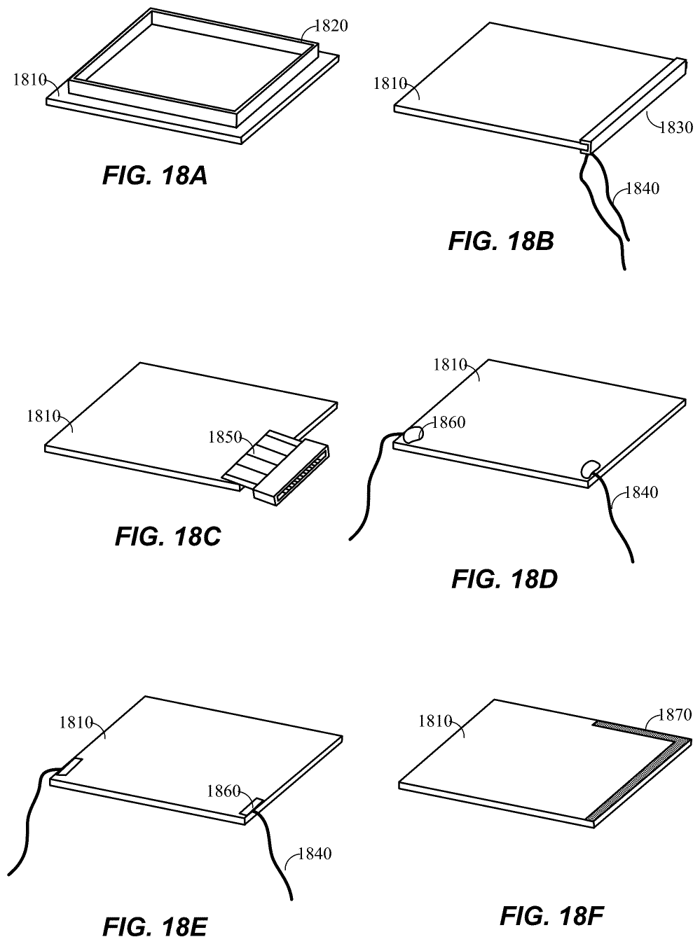

FIGS. 18A-18F illustrate various configurations of PV contacts on example IGUs according to certain embodiments. The IGUs may include an assembly 1810 including a glass pane and a PV layer. In the embodiment shown in FIG. 18A, a conductive epoxy or adhesive may be formed on a spacer 1820 for making contact with the PV layer in assembly 1810. FIG. 18B shows that a conductive press fitting 1830 may be attached to an edge of assembly 1810 for making contact with the PV layer at the edge of assembly 1810 and transporting electrical power using electrical wires 1840. In the embodiment shown in FIG. 18C, a flex-on-glass (FOG) anisotropic conductive adhesive 1850 may be attached to an edge of assembly 1810 for connecting the PV layer in assembly 1810 to a connector. FIG. 18D shows that soldered connections may be used for making contact with the PV layer in assembly 1810 and transporting electrical power using electrical wires 1840. FIG. 18E shows that conductive tapes may be used for making contact with the PV layer in assembly 1810 and transporting electrical power using electrical wires 1840. FIG. 18F shows that a busbar may be formed on the PV layer for making contact with the PV layer in assembly 1810 and for transporting electrical power from one area of the PV layer to another area of the PV layer where a power-consuming device may be located.

As described above, in addition to the PV layer, other material layers may also be integrated into the IGUs. The PV layer may be paired with these material layers to provide power to these material layers, which may perform one or more functions. Some examples of these material layers may include low emissivity (low-E) materials/layers for IR reflection, other reflective materials/layers, color tint materials/layers, color neutrality balancing materials/layers, anti-reflection materials/layers, other materials/layers for changing solar heating, conductivity modification layers, surface energy modification layers (that may affect how materials grow on the underlying layer), surface work-function modification layers, surface roughness modification layers, etc. In some embodiments, one or more of the functional layers or the PV layer may be multi-functional.

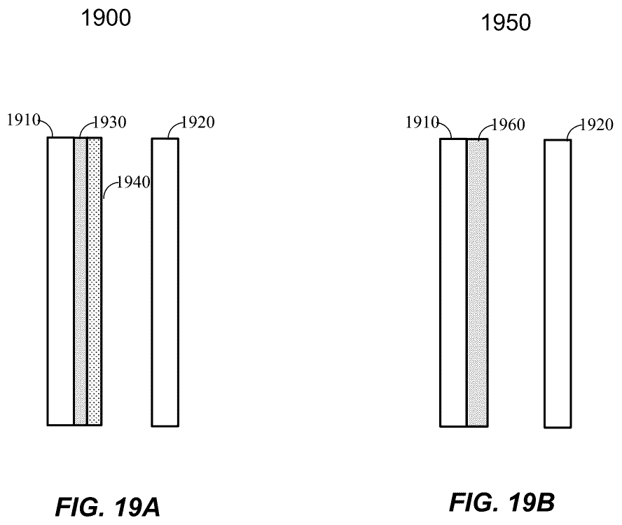

FIGS. 19A-19B illustrate example IGUs including other functional layer(s) in addition to a PV layer according to certain embodiments. FIG. 19A illustrates an example IGU 1900 having a first glass pane 1910, a second glass pane 1920, a PV layer 1930, and a functional layer 1940 paired with PV layer 1930. The paired layers of functional layer 1940 and PV layer 1930 may perform additional function(s) other than converting solar power to electrical power. For example, an additional functional layer may include a color tint material that can act as a low-E or anti-reflective material and can also balance color neutrality. FIG. 19B illustrates an example IGU 1950 including first glass pane 1910, second glass pane 1920, and a multi-functional layer 1960. Multi-functional layer 1960 may include one or more material layers that can perform multiple functions. For example, a multi-functional layer may act as a PV layer and may also act as a low-E, color tint, and/or reflective layer, etc.

The additional functional layers may be arranged with the PV layer in various combinations. For example, the layers can be arranged in any order on a same inner or outer surface of a glass pane of an IGU.

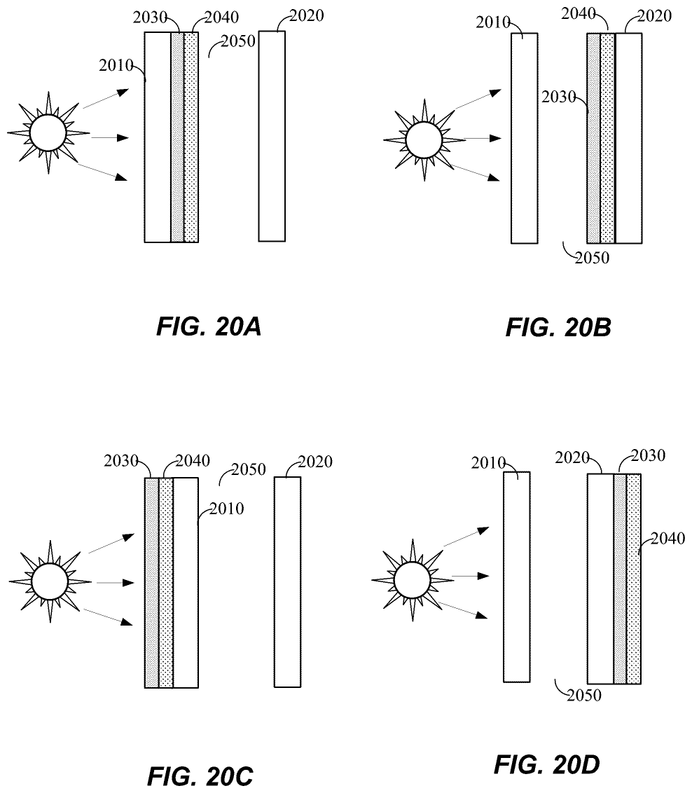

FIGS. 20A-20D illustrate various configurations of example IGUs including other functional layer(s) (e.g., a low-E layer) in addition to the PV layer according to certain embodiments. For example, in the embodiment shown in FIG. 20A, the IGU may include a first glass pane 2010 and a second glass pane 2020 that form a gap 2050. A PV layer 2030 is attached to the inner surface of first glass pane 2010 that faces gap 2050, and a functional layer 2040 is coupled to a surface of PV layer 2030 opposite to first glass pane 2010. In the embodiment shown in FIG. 20B, functional layer 2040 is attached to the inner surface of second glass pane 2020 that faces gap 2050, and PV layer 2030 is coupled to a surface of functional layer 2040 opposite to second glass pane 2020. In the embodiment shown in FIG. 20C, functional layer 2040 is attached to the outer surface of first glass pane 2010 that faces the external environment, and PV layer 2030 is coupled to a surface of functional layer 2040 opposite to first glass pane 2010. In the embodiment shown in FIG. 20D, PV layer 2030 is attached to the outer surface of second glass pane 2020 that faces the interior of a building, and functional layer 2040 is coupled to a surface of PV layer 2030 opposite to second glass pane 2020.

In some embodiments, the additional functional layer and the PV layer may be arranged on opposite surfaces of any glass pane of an IGU. In some embodiments, the additional functional layer and the PV layer may be arranged on different glass panes of an IGU. In some embodiments, multiple functional layers may be used in a same IGU, and may be arranged with the PV layer according to any suitable configuration. In yet some embodiments, multiple PV layers may be used in an IGU, and may be arranged (with the functional layers if any) according to any suitable configuration. The functional layers may perform various functions as described above and below in the present disclosure.

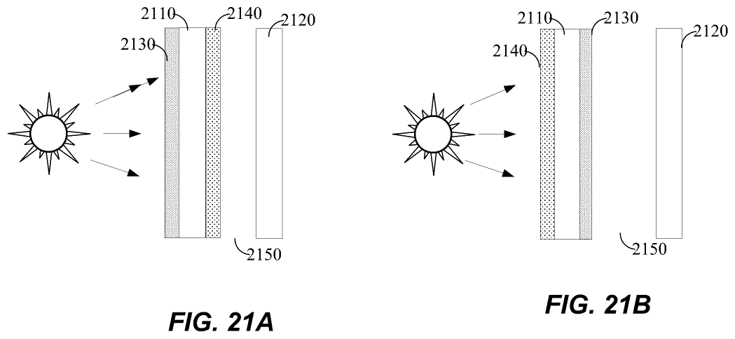

FIGS. 21A-21B illustrate example IGUs including a functional layer 2140 and a PV layer 2130 on a same IGU glass pane according to certain embodiments. The example IGUs may each include a first glass pane 2110 and a second glass pane 2120 that form a gap 2150. In the embodiment shown in FIG. 21A, PV layer 2130 may be placed on the outer surface of first glass pane 2110 facing the external environment, and functional layer 2140 may be placed on the inner surface of first glass pane 2110 adjacent to gap 2150. In the embodiment shown in FIG. 21B, functional layer 2140 may be placed on the outer surface of first glass pane 2110 facing the external environment, while PV layer 2130 may be placed on the inner surface of first glass pane 2110 adjacent to gap 2150.

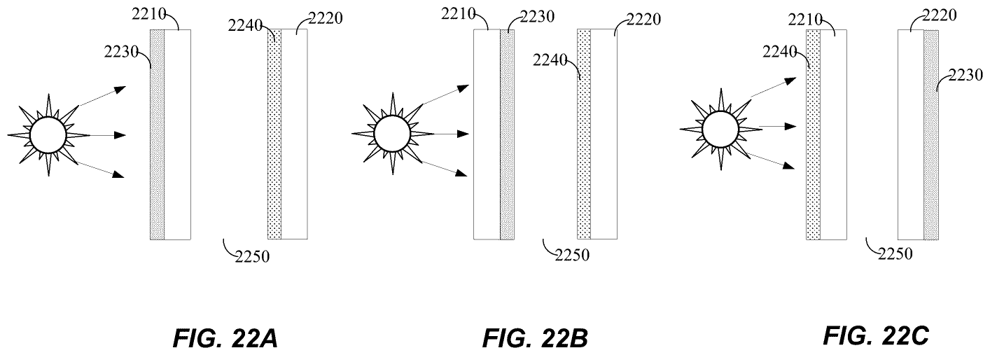

FIGS. 22A-22C illustrate example IGUs each including a functional layer 2240 and a PV layer 2230 on different glass panes of the IGU according to certain embodiments. The example IGUs may each include a first glass pane 2210 and a second glass pane 2220 that form a gap 2250. In the embodiment shown in FIG. 22A, PV layer 2230 may be placed on the outer surface of first glass pane 2210 facing the external environment, and functional layer 2240 may be placed on the inner surface of second glass pane 2220 adjacent to gap 2250. In the embodiment shown in FIG. 22B, PV layer 2230 may be placed on the inner surface of first glass pane 2210 adjacent to gap 2250, while functional layer 2240 may be placed on the inner surface of second glass pane 2220 adjacent to gap 2250. In the embodiment shown in FIG. 22C, functional layer 2240 may be placed on the outer surface of first glass pane 2210 facing the external environment, while PV layer 2230 may be placed on the outer surface of second glass pane 2220 facing the interior of the building.

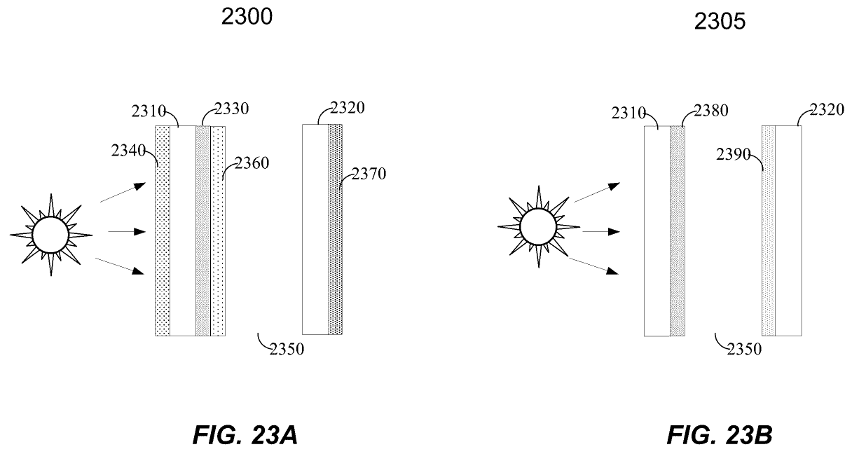

FIG. 23A illustrates an example IGU 2300 including multiple functional layers according to certain embodiments. IGU 2300 may include a first glass pane 2310 and a second glass pane 2320 that form a gap 2350. A PV layer 2330 may be placed on the inner surface of first glass pane 2310 adjacent to gap 2350. A first functional layer 2340 may be placed on the outer surface of first glass pane 2310 facing the external environment. A second functional layer 2360 may be placed next to PV layer 2330. A third functional layer 2370 may be placed on the outer surface of second glass pane 2320 facing the interior of the building.

FIG. 23B illustrates an example IGU 2305 including multiple PV layers according to certain embodiments. IGU 2305 may include first glass pane 2310 and second glass pane 2320 that form gap 2350. A first PV layer 2380 may be placed on the inner surface of first glass pane 2310 adjacent to gap 2350, and a second PV layer 2390 may be placed on the inner surface of second glass pane 2320 adjacent to gap 2350.

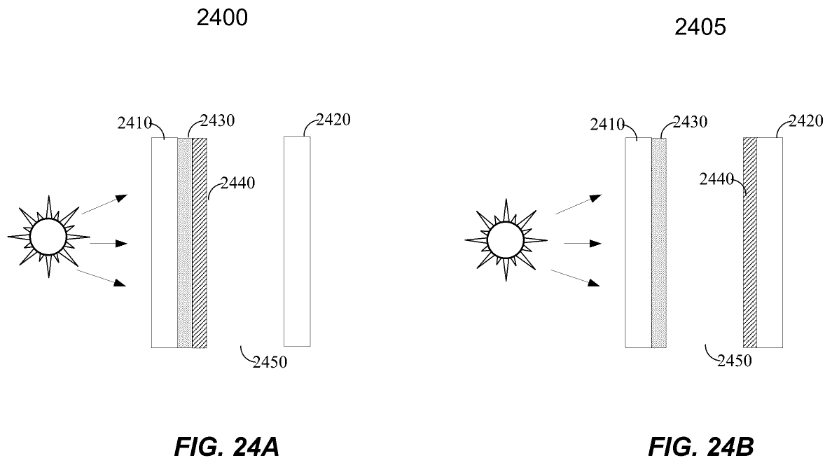

FIGS. 24A-24B illustrate example IGUs including a low-Emissivity (low-E) layer 2440 according to certain embodiments. Low-E coatings may be very effective at reflecting IR light. When a PV module is integrated with a low-E coating that is after the PV layer in the solar light path, the IR light reflected by the low-E coating back to the PV layer can increase the NIR absorption in the PV layer, leading to an increase in the overall power conversion efficiency of the PV layer and a reduction of heat transmittance into the building. FIG. 24A shows an example IGU 2400 including a first glass pane 2410 and a second glass pane 2420 that form a gap 2450. A PV layer 2430 may be placed on the inner surface of first glass pane 2410 adjacent to gap 2450. A low-E layer 2440 may be placed next to PV layer 2430. Solar light passing through first glass pane 2410 and reaching PV layer 2430 may be partially absorbed by PV layer 2430. The portion of the solar light that may reach low-E layer 2440 may be reflected back to PV layer 2430 by low-E layer 2440 and at least partially absorbed by PV layer 2430. In IGU 2405 shown in FIG. 24B, PV layer 2430 may be placed on the inner surface of first glass pane 2410 adjacent to gap 2450. Low-E layer 2440 may be placed on the inner surface of second glass pane 2420 adjacent to gap 2450. Solar light passing through first glass pane 2410 and reaching PV layer 2430 may be partially absorbed by PV layer 2430. The portion of the solar light that may pass through gap 2450 and reach low-E layer 2440 may be reflected back to PV layer 2430 by low-E layer 2440 and at least partially absorbed by PV layer 2430.

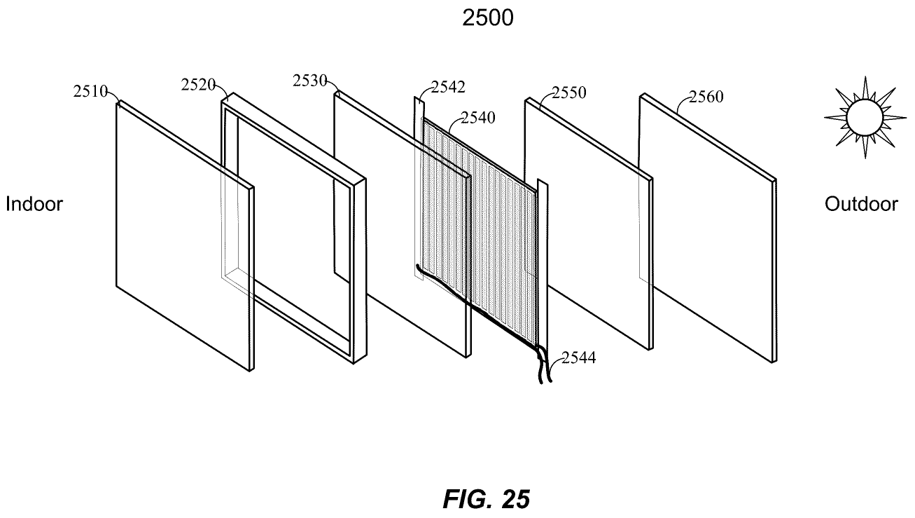

FIG. 25 is an exploded view of an example IGU 2500 according to certain embodiments. IGU 2500 may be integrated into a skylight assembly and a PV module in IGU 2500 may be used to power the skylight mechanical lift, power other components, or feed back into the power grid in the building. IGU 2500 may include a first glass pane 2510 (or glass lite) that faces the interior of the building, and a second glass pane 2560 that faces the external environment of the building. A PV barrier layer 2550 may be coated with a PV layer 2540 and may be attached to the inner surface of second glass pane 2560. PV layer 2540 may be electrically connected to busbars 2542 and electrical wires 2544. A third glass pane 2530 may be attached to PV layer 2540 to encapsulate and protect PV layer 2540. Second glass pane 2560, PV barrier layer 2550, PV layer 2540, busbars 2542, electrical wires 2544, and third glass pane 2530 may form a PV assembly. The PV assembly, first glass pane 2510, and an IGU spacer 2520 may be assembled together to form the IGU, where IGU spacer 2520 may separate the PV assembly and first glass pane 2510 to form an internal gap in the IGU.

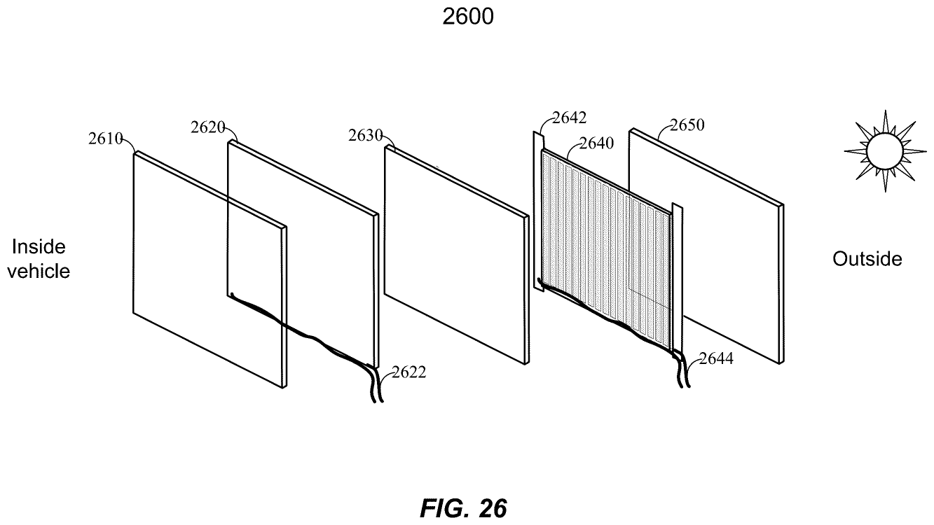

FIG. 26 is an exploded view of an example IGU 2600 including an electrochromic layer 2620 according to certain embodiments. IGU 2600 may be used as, for example, a sunroof assembly for a vehicle or as a window of a vehicle or a building. IGU 2600 may include a PV module that can be used to power automatic window tinting or power other components near the sunroof or the window. The power generated may be used when the car is off, on, or both. In some embodiments, IGU 2600 may include a first glass pane 2610 (or glass lite) that faces the interior of the vehicle, and a second glass pane 2650 that faces the external environment of the vehicle. A PV layer 2640 may be coated on second glass pane 2650, and may be covered and protected by a PV barrier layer 2630. PV layer 2640 may be electrically connected to busbars 2642 and electrical wires 2644. Electrochromic layer 2620 may be placed between first glass pane 2610 and PV barrier layer 2630, and may be connected to electrical wires 2622 for receiving power from a power source. For example, electrical wires 2622 may be connected to electrical wires 2644 to receive power from PV layer 2640. Electrochromic layer 2620 may change optical properties such as color, optical transmission, absorption, reflectance, and/or emittance in a continual but reversible manner when different voltage levels are applied to it.

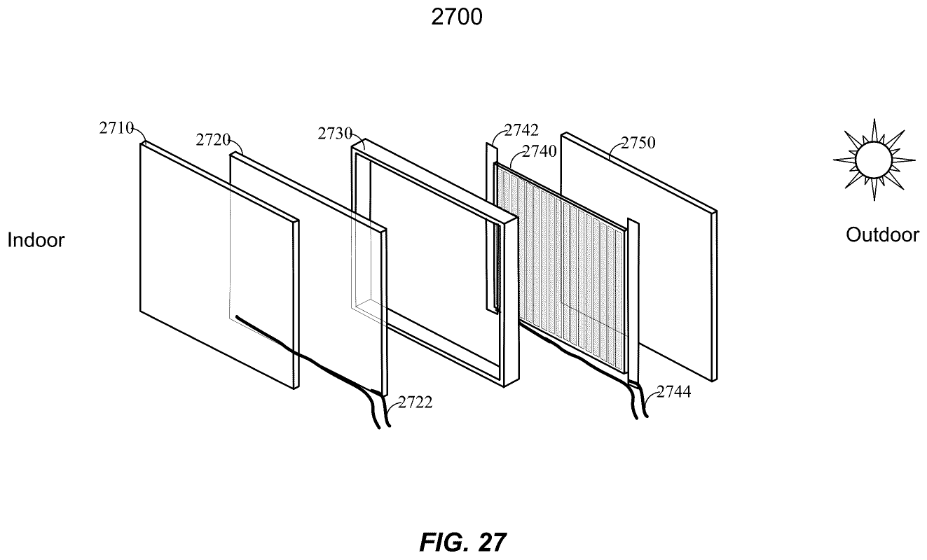

FIG. 27 is an exploded view of an example IGU 2700 including an electrochromic layer 2720 according to certain embodiments. IGU 2700 may be used as a smart window assembly for a building or other structures. IGU 2700 may include a PV module that can be used to power an electrochromic window directly or charge an internal battery that provides power to the electrochromic window. In some embodiments, IGU 2700 may include a first glass pane 2710 (or glass lite) that faces the interior of the building or other structures, and a second glass pane 2750 that faces the external environment of the building or the structures. A PV layer 2740 may be coated on second glass pane 2750. PV layer 2740 may be electrically connected to busbars 2742 and electrical wires 2744. Electrochromic layer 2720 may be placed on inner surface of first glass pane 2710 and may be connected to electrical wires 2722 for receiving power from a power source. For example, electrical wires 2722 may be connected to electrical wires 2744 to receive power from PV layer 2740. Electrochromic layer 2720 may change optical properties such as color, optical transmission, absorption, reflectance, and/or emittance in a continual but reversible manner when different voltage levels are applied to it. Second glass pane 2750 coated with PV layer 2740, first glass pane 2710 coated with electrochromic layer 2720, and an IGU spacer 2730 may be assembled together to form the IGU, where IGU spacer 2730 may separate first glass pane 2710 and second glass pane 2750 to form an internal gap in the IGU.

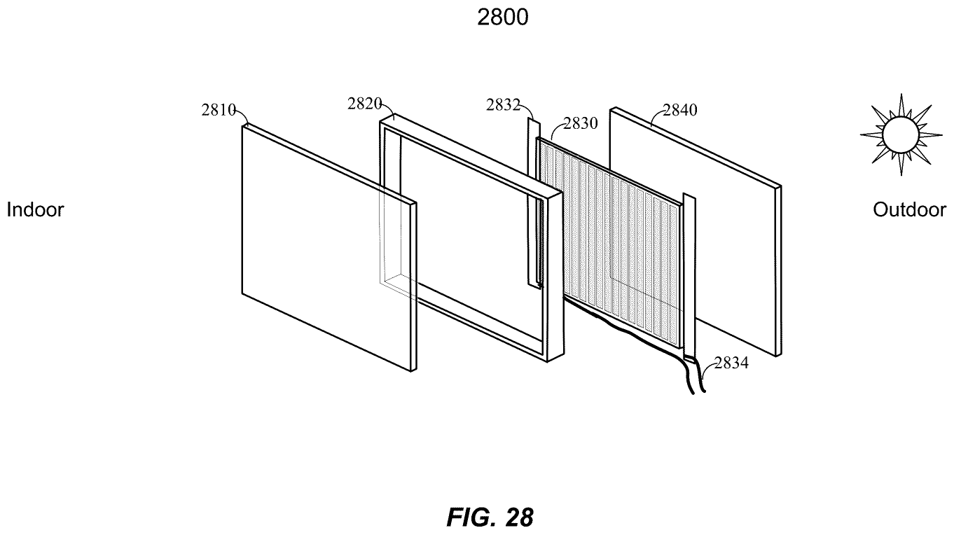

FIG. 28 is an exploded view of an example IGU 2800 according to certain embodiments. IGU 2800 may be used as a building IGU. A PV module may be integrated into IGU 2800. The PV power generated by the PV module can then be connected to a DC-to-AC inverter and be fed into the power grid of the building or a smart grid. In some embodiments, IGU 2800 may include a first glass pane 2810 (or glass lite) that faces the interior of the building, and a second glass pane 2840 that faces the external environment of the building. A PV layer 2830 may be formed on second glass pane 2840. PV layer 2830 may be electrically connected to busbars 2832 and electrical wires 2834. Electrical wires 2834 may be connected to a DC electrical device or a DC-to-AC inverter. Second glass pane 2840 coated with PV layer 2830, first glass pane 2810, and an IGU spacer 2820 may be assembled together to form IGU 2800, where IGU spacer 2820 may separate first glass pane 2810 and second glass pane 2840 to form an internal gap in the IGU.

It is noted that, in the above example IGUs, even though functional layers, low-E layers, encapsulation layers, and/or sealants may not be shown in the figures or explicitly described in order not to obscure the features being described, a skilled person would readily understand that various combinations of these layers and sealants may be used in any IGU described above.

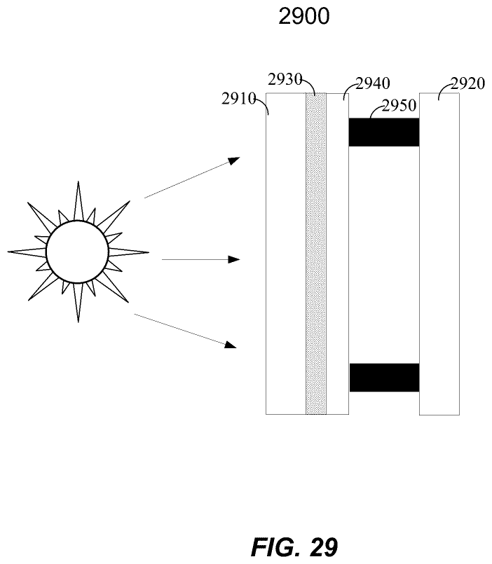

FIG. 29 illustrates the configuration of an example IGU 2900 according to certain embodiments. IGU 2900 includes PV layer(s) 2930 deposited on a first glass pane 2910 (e.g., a 12″×12″×1.1 mm piece of glass). An encapsulation glass 2940 (e.g., a 12″×11.5″×2.5 mm piece of glass) may be bonded to the top surface of PV layer(s) 2930 using an optically clear UV-curably epoxy, thermal curable epoxy, or pressure-thermal adhesive, such as polyvinyl alcohol (PVA), Polyvinyl butyral (PVB), or thermoplastic polyurethane (TPU). Busbars (not shown in FIG. 29) may be added with silver paste along two edges of PV layer(s) 2930 that may be left exposed after encapsulation. Wires for electrical contact may be secured to each side of IGU 2900 via soldering and/or copper tape. A spacer 2950 (e.g., with dimensions of 11.5″×11.5″×0.5″) may be bonded directly to encapsulation glass 2940 and a second glass pane 2920 (e.g., a 12″×12″×2.5 mm piece of glass).

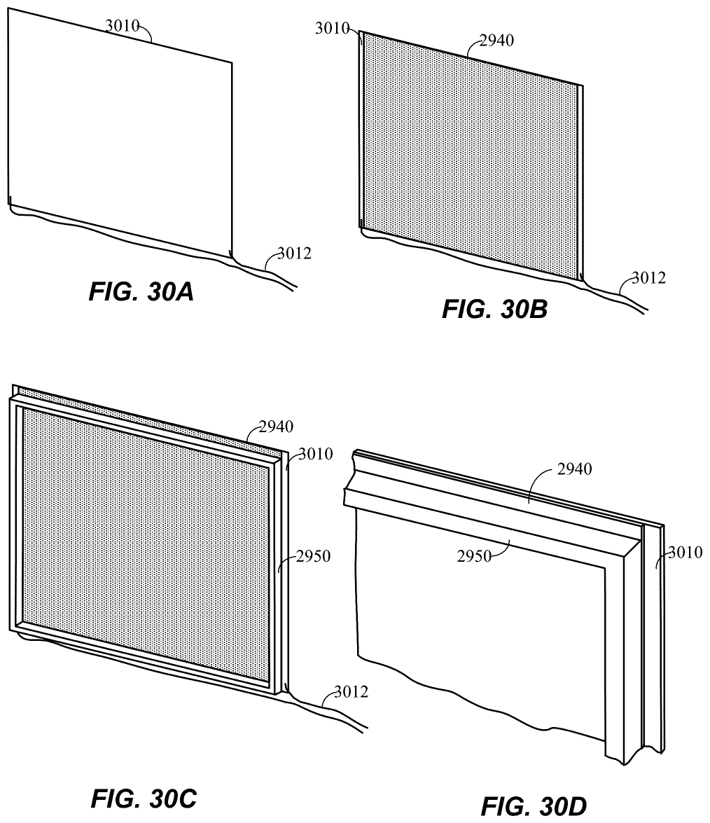

FIGS. 30A-30D illustrate various components of example IGU 2900 shown in FIG. 29 according to certain embodiments. FIG. 30A shows an assembly 3010 including PV layer(s) 2930 and first glass pane 2910. Assembly 3010 may also include electrical wires 3012 connected to the PV layer(s). FIG. 30B shows that encapsulation glass 2940 may be bonded to the top surface of PV layer(s) 2930 using an optically clear UV-curably epoxy, thermal curable epoxy, or pressure-thermal adhesive, such as PVA, PVB, or TPU. Encapsulation glass 2940 may have the same dimension as first glass pane 2910 in one direction (e.g., vertical direction shown in FIG. 30B) and may be slightly (e.g., about 0.5″) shorter than first glass pane 2910 in another direction (e.g., horizontal direction). Certain areas near two vertical edges of PV layer(s) 2930 may be exposed (uncovered) after encapsulation glass 2940 is bonded to PV layer(s) 2930. Busbars or other electrical connections may be formed on the exposed areas for making contact with PV layer(s) 2930. FIG. 30C shows that spacer 2950 can be bonded to encapsulation glass 2940. FIG. 30D shows that spacer 2950 may be slightly (e.g., about 0.5″) shorter than assembly 3010 in both directions. Thus, the electrical connections to PV layer(s) 2930 can be made outside of spacer 2950 and do not have to pass through spacer 2950 in order to bring the generated electrical power out of IGU 2900. IGU 2900 may be sealed around the outer edges of spacer 2950 using, for example, a silicone sealant, leaving electrical wires 3012 exposed for electrical contact with PV layer(s) 2930.

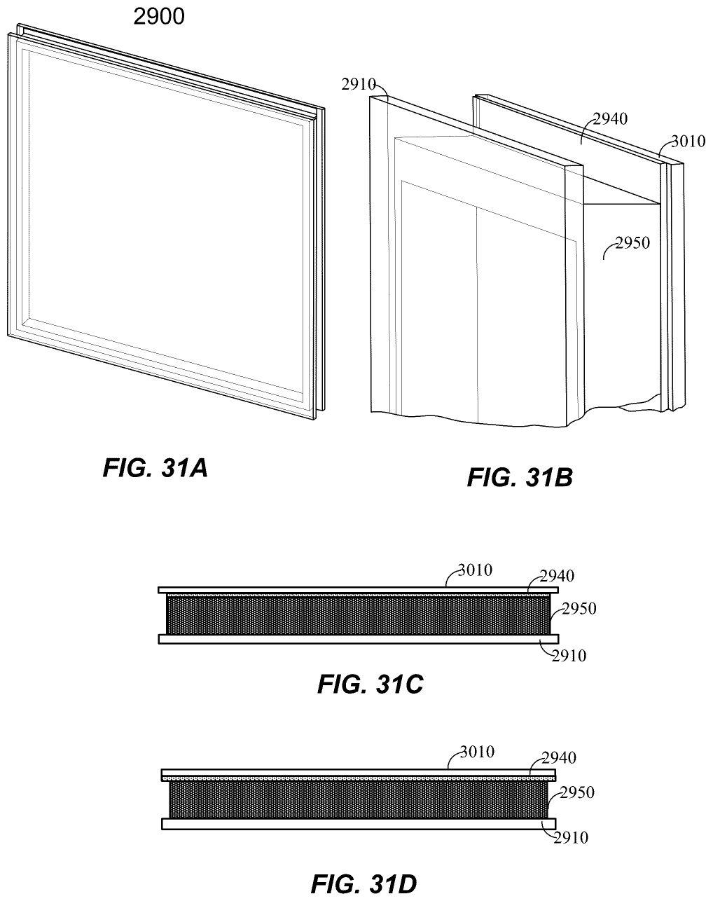

FIGS. 31A-31D show the fully assembled example IGU 2900 of FIG. 29 according to certain embodiments. FIG. 31A is a perspective view of the fully assembled IGU 2900. FIG. 31B is a zoom-in perspective view of a portion of IGU 2900. FIG. 31C is a horizontal cross-sectional view of IGU 2900. FIG. 31C is a vertical cross-sectional view of IGU 2900. As shown in FIGS. 31B and 31D, the top edge of encapsulation glass 2940 may be aligned with assembly 3010 and thus may make it easy to assemble the IGU. As shown in FIGS. 31B and 31C, the areas near the left and right edges of assembly 3010 may not be covered by encapsulation glass 2940 or spacer 2950, and may thus be used for making electrical connections with PV layer(s) 2930 without having to pass through spacer 2950.

To estimate the impact that the transparent PV layers integrated into a dual-pane window combined with low-E functionality could have on the energy consumption of an entire building for heating and cooling, building energy simulations may be performed. In the example described below, a series of annual building energy simulations are performed on a typical medium-sized office building in three different climate zones to predict the impact of integrating a transparent PV layer with added low-E functionality in dual-pane windows on energy savings for a building. The transparent PV layer is selected to have selective absorption and reflection in the NIR range.

A standalone low-E layer (referred to as “Low-E”) and an example transparent PV (TPV) layer stack with added low-E functionality (referred to as “TPV+Low-E”) are used for integration into the dual-pane windows. The optical properties (e.g., transmission and reflection) of the low-E and TPV+Low-E coatings are measured.

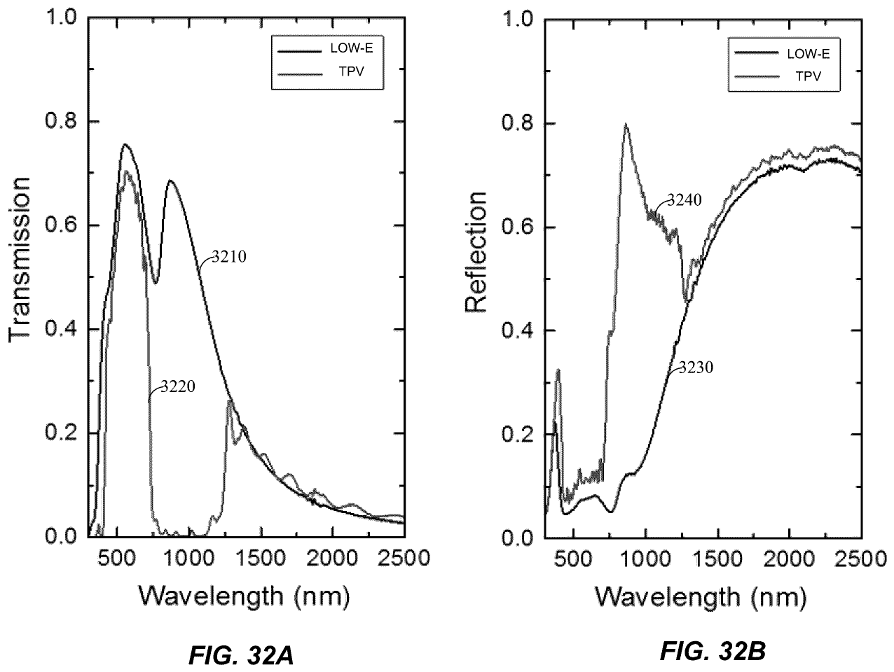

FIG. 32A illustrates transmission spectra of two materials (Low-E and TPV+Low-E) according to certain embodiments. The transmission spectra of the Low-E coating is shown by curve 3210, and the transmission spectra of TPV+Low-E coating is shown by curve 3220. FIG. 32A shows that both coatings have high transmission rates for visible light, and TPV+Low-E also has low transmission rates for NIR light.

FIG. 32B illustrates reflection spectra of two materials (Low-E and TPV+Low-E) according to certain embodiments. The reflection spectra show the reflection rates of the PV material for light incident from the front of the PV material. The reflection spectrum of the Low-E coating is shown by curve 3230, and the reflection spectrum of TPV+Low-E coating is shown by curve 3240. FIG. 32B shows that both materials have high reflection rates for IR light with wavelengths greater than 1200 nm, and the TPV+Low-E coating may also have high reflection rates for NIR light with wavelengths less than 1200 nm.

“Optics 6” software from Lawrence Berkeley National Lab is used to determine window simulation values for the Low-E and TPV+Low-E coatings using the measured optical properties (e.g., transmittance, front and back reflectance and emissivity, etc.) of the Low-E and TPV+Low-E coatings. Subsequently, key physical parameters that can be used to model window assemblies for clear glass and low-E glass are obtained from Lawrence Berkeley National Lab's Windows database. Table 1 shows a comparison of these parameters for the clear glass, low-E glass, and glass with TPV+Low-E coating. Subscripts in Table 1 indicate the portion of the solar spectrum (e.g., “sol” refers to solar, “vis” refers to visible). The numerals in the parameters in Table 1 indicate front (“1”) and back (“2”) surfaces, ε represents infrared emissivity, and k represents thermal conductivity.

TABLE 1
Simulation parameters for different types of glasses

| | Tₛₒₗ | Rₛₒₗ₁ | Rₛₒₗ₂ | Tᵥᵢₛ | Rᵥᵢₛ₁ | Rᵥᵢₛ₂ | ε₁ | ε₂ | k (W/m-K) |
|---|---|---|---|---|---|---|---|---|---|
| Clear Glass | 0.786 | 0.071 | 0.071 | 0.891 | 0.081 | 0.081 | 0.84 | 0.84 | 1.00 |
| Low-E | 0.513 | 0.196 | 0.278 | 0.725 | 0.072 | 0.060 | 0.84 | 0.02 | 1.00 |
| TPV + Low-E | 0.267 | 0.399 | 0.633 | 0.663 | 0.110 | 0.118 | 0.84 | 0.02 | 1.00 |

“Berkeley Lab WINDOW” software from Lawrence Berkeley National Lab is used for analyzing thermal and optical performance of different window configurations described below. Using window properties, the standard metrics of visible transmittance, solar heat gain coefficient (SHGC), and U-Value (representing overall heat transfer coefficient) of three window configurations with and without the TPV coatings are calculated. For the propose of building simulations, it is assumed that the reference building comprises dual-pane windows since these windows are the new industry standard. It is also assumed that the dual-pane windows comprise two 6-mm-thick glass panes and the air gap between the glass panes is about 6 mm.

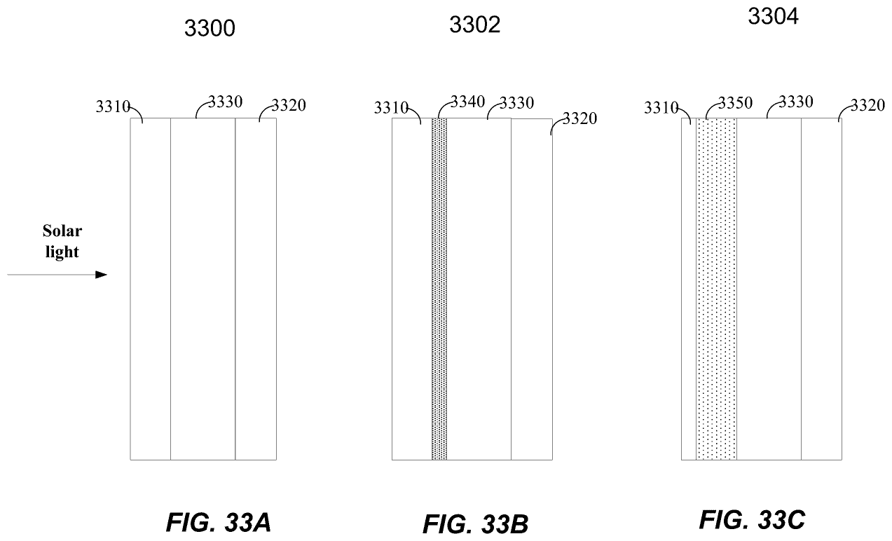

FIG. 33A illustrates an example IGU 3300 with clear glass. IGU 3300 may include a first glass pane 3310 and a second glass pane 3320 that form an internal gap 3330. First glass pane 3310 may face the external environment of the building, and second glass pane 3320 may face the interior of the building. FIG. 33B illustrates an example IGU 3302 including a low-E layer 3340. IGU 3302 may include first glass pane 3310 and second glass pane 3320 that form internal gap 3330. Low-E layer 3340 may be placed on the inner surface of first glass pane 3310. FIG. 33C illustrates an example IGU 3304 including a transparent PV layer according to certain embodiments. IGU 3304 may include first glass pane 3310 and second glass pane 3320 that form internal gap 3330. A TPV coating 3350 (which may also include a low-E layer) may be formed on the inner surface of first glass pane 3310.

The simulations use a sophisticated model that uses data from Table 1 to model the energy characteristics of the window. The model takes into account angular variation in window properties, and treats each portion of the solar spectrum separately. Table 2 shows the U-Value, SHGC, and VT values calculated for the example IGU configurations shown in FIGS. 33A-33C.

TABLE 2
Parameters calculated for different window configurations

| | U-Value | SHGC | VT |
|---|---|---|---|
| Dual Pane with air gap (Reference) | 3.114 | 0.717 | 0.798 |
| Dual Pane with air gap and low-E coating | 2.329 | 0.500 | 0.649 |
| Dual Pane with air gap and TPV + Low-E | 2.329 | 0.289 | 0.596 |

The U-value in Table 2 represents the overall heat transfer coefficient that describes how well a building element conducts heat. Lower U-values imply higher levels of insulation and hence are generally preferred for window assemblies. As shown in Table 2, the addition of a Low-E or TPV+Low-E coating to a dual-pane window can substantially decrease the U-value of the dual-pane window.

The SHGC indicates the fraction of incident solar radiation admitted through a window, including both the portion directly transmitted and the portion absorbed first and subsequently released inward. The lower a window's SHGC, the less solar heat the window transmits and hence, the lower the cooling requirement in the summer. Solar heat gain may be affected by the glazing type, the number of panes, and any glass coatings. A typical dual-pane window may have a SHGC of around 0.72. This value may be decreased significantly to, for example, about 0.5, by adding a low-E coating. As shown in Table 2, a dual-pane window with a TPV+Low-E coating has a significantly lower SHGC value of about 0.29 due to the selective absorption and reflection of NIR light with wavelengths less than 1200 nm and the reflection of infrared light with wavelengths greater than 1200 nm by the low-E coating.

Although these standard window metrics are widely accepted and understood, they fail to capture some of the advantages of advanced technologies, such as power producing layers in the windows. To address these issues, annual whole building energy simulations are performed to simulate energy performance in three representative climates across the United States to fully determine the benefits of adding PV layers to windows.

A medium-sized commercial reference building model developed by the U.S. Department of Energy (DOE) is used to simulate energy performance in three climates: Phoenix, AZ, Chicago, IL, and Baltimore, MD. The building model is designed to comply with ASHRAE 90.1-2004 building energy code and represent typical new construction. The medium-sized reference building model includes 3 floors and the total simulated floor area is about 53,600 ft². The model has about 7027 ft² of window area representing a window-to-wall ratio of about 33%. The windows are evenly distributed along the four façades. Each floor has four perimeter zones and one core zone. Perimeter and core zones comprise 40% and 60% of the total area, respectively. Floor-to-floor height is about 13 ft and floor-to-ceiling height is about 9 ft. The difference in height represents plenum height.

The Energy Plus software is used to perform the building energy simulations. The total building cooling and heating energy consumption for each window configuration and each location is calculated using the Energy Plus software. Power produced by the TPV-coated windows is estimated using average solar illumination data for each location obtained from National Renewable Energy Lab (NREL).

Table 3 illustrates the heating, ventilation, and air conditioning (HVAC) energy consumption for different window configurations in different geographical locations. The annual heating and cooling energy requirements represent the amount of thermal energy that must be delivered to or removed from a building by the HVAC system to maintain the desired thermostat set point. Both low-E and TPV+Low-E-coated windows result in a decreased need for HVAC energy in all climates compared with the baseline dual-pane window, with significantly higher HVAC reductions for the TPV+Low-E-coated window. Furthermore, PV power generated by the TPV-coated windows is estimated using the average solar illumination intensity data from NREL and assuming 5% PV efficiency. With a combination of the PV power generated and the HVAC savings, windows including TPV coating may lead to about 40-50% reduction in power consumption by typical buildings. This is a substantial amount of saving in building energy consumption and shows the large impact that the TPV coating can have on building-integrated photovoltaic modules.

TABLE 3
Heating and cooling energy requirements for different window configurations

| | | | | | HVAC | % age | | Total Savings + | |
|---|---|---|---|---|---|---|---|---|---|
| | Window | Heating | Cooling | Total HVAC | Savings | HVAC | PV Power | Generation | Benefit |
| Location | Config. | (kWh/m²/yr) | (kWh/m²/yr) | (kWh/m²/yr) | (kWh/m²/yr) | Savings | (kWh/m²/yr) | (kWh/m²/yr) | (%) |
| Phoenix | Reference | 33.92 | 391.97 | 425.90 | | | | | |
| | Low-E | 25.04 | 359.29 | 384.33 | 41.57 | 9.8 | 118.08 | 159.65 | 37.5 |
| | TPV + Low-E | 23.09 | 306.92 | 330.01 | 95.89 | 22.5 | 118.08 | 213.97 | 50.2 |
| Chicago | Reference | 214.22 | 173.52 | 387.74 | | | | | |
| | Low-E | 176.29 | 159.90 | 336.19 | 51.55 | 13.3 | 79.75 | 131.3 | 33.9 |
| | TPV + Low-E | 179.02 | 134.17 | 313.19 | 74.55 | 19.2 | 79.75 | 154.3 | 39.8 |
| Baltimore | Reference | 159.79 | 214.39 | 374.18 | | | | | |
| | Low-E | 131.47 | 195.95 | 327.42 | 46.76 | 12.5 | 83.22 | 129.88 | 34.7 |
| | TPV + Low-E | 136.95 | 164.59 | 301.54 | 72.64 | 19.4 | 83.22 | 155.86 | 41.7 |

It should be appreciated that the specific steps and devices described herein provide a particular method of making a visibly transparent photovoltaic module according to an embodiments of the present invention. Other sequences of steps may also be performed according to alternative embodiments. For example, alternative embodiments of the present invention may perform the steps outlined above in a different order. Moreover, the individual steps and devices described herein may include multiple sub-steps that may be performed in various sequences as appropriate to the individual embodiments. Furthermore, additional steps and components be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

1. An electricity generating window comprising:
a first glass pane including an inner surface;
a second glass pane including an inner surface; and
a photovoltaic device formed on the inner surface of the first glass pane or the inner surface of the second glass pane, the photovoltaic device comprising:
a first transparent electrode layer;
a second transparent electrode layer; and
one or more active layers configured to absorb ultraviolet or near-infrared light and transmit visible light.

2. The electricity generating window of claim 1, further comprising:
a first busbar in contact with the first transparent electrode layer;
a second busbar in contact with the second transparent electrode layer; and
a spacer separating the first glass pane and the second glass pane by a cavity,
wherein the spacer forms a closed loop outside a perimeter of the photovoltaic device but within a perimeter of the first glass pane or the second glass pane; and
wherein the first busbar and second busbar are within a perimeter formed by the spacer or underneath the spacer, each of the first busbar and second busbar extending along an edge of the photovoltaic device.

3. The electricity generating window of claim 2, further comprising an encapsulation layer on the photovoltaic device and within the perimeter formed by the spacer.

4. The electricity generating window of claim 3, wherein the encapsulation layer comprises one or more thin film encapsulation layers.

5. The electricity generating window of claim 3, wherein the encapsulation layer comprises a low emissivity (low-E) layer for reflecting infrared light.

6. The electricity generating window of claim 3, wherein the encapsulation layer comprises a glass panel or a laminated barrier layer.

7. The electricity generating window of claim 2, further comprising two wires, each wire electrically connected to the first busbar or the second busbar and passing through the spacer via an air-tight seal in the spacer.

8. The electricity generating window of claim 1, where the photovoltaic device is configured to act both as a photovoltaic device and as a low-E layer for reflecting infrared light.

9. The electricity generating window of claim 1, further comprising:
a low-E layer configured to reflect infrared light,
wherein the low-E layer is positioned on the photovoltaic device or on a different glass pane than the photovoltaic device.

10. The electricity generating window of claim 9, further comprising an encapsulation layer positioned between the photovoltaic device and the low-E layer.

11. The electricity generating window of claim 1, wherein:
the photovoltaic device is laminated between the first glass pane and the second glass pane.

12. The electricity generating window of claim 1, further comprising a functional device electrically coupled to the photovoltaic device.

13. The electricity generating window of claim 12, wherein the functional device includes an electrochromic device.

14. A method of fabricating an electricity generating window, the method comprising:
forming a photovoltaic device on a top surface of a first glass pane, the photovoltaic device comprising:
a first transparent electrode layer;
one or more active layers configured to absorb ultraviolet or near-infrared light and transmit visible light; and
a second transparent electrode layer; and
attaching a second glass pane on top of the photovoltaic device, wherein the second glass pane is separate from the photovoltaic device by a distance.

15. The method of claim 14, further comprising:
forming a first busbar in contact with the first transparent electrode layer;
forming a second busbar in contact with the second transparent electrode layer; and
depositing an encapsulation layer on the photovoltaic device.

16. The method of claim 15, wherein:
attaching the second glass pane on top of the photovoltaic device comprises:
attaching a spacer on the encapsulation layer; and
attaching the second glass pane on the spacer;
the spacer forms a closed loop outside a perimeter of the photovoltaic device but within a perimeter of the first glass pane or the second glass pane; and
the first busbar and second busbar are within a perimeter formed by the spacer or underneath the spacer, each of the first busbar and second busbar extending along an edge of the photovoltaic device.

17. The method of claim 15, wherein depositing the encapsulation layer on the photovoltaic device comprises depositing one or more thin film layers.

18. The method of claim 14, further comprising:
forming a low-E layer for reflecting infrared light on a bottom surface of the second glass pane or above the photovoltaic device before attaching the second glass pane on top of the photovoltaic device.

19. The method of claim 14, further comprising:
forming an electrochromic layer on the second glass pane or above the photovoltaic device; and
electrically coupling the electrochromic layer to the photovoltaic device.

20. An electrochromic window comprising:
a first glass pane including an inner surface;
a photovoltaic device formed on the inner surface of the first glass pane, the photovoltaic device comprising:
a first transparent electrode layer,
a second transparent electrode layer, and
one or more active layers configured to absorb ultraviolet or near-infrared light and transmit visible light;
a barrier layer;
a second glass pane; and
an electrochromic layer between the barrier layer and the second glass pane, the electrochromic layer electrically coupled to the first transparent electrode layer and the second transparent electrode layer.
